(19) United States
(12) Patent Application Publication
(10) Pub. No.: US 2026/0159530 A1
(43) Pub. Date: Jun. 11, 2026

(54) STRONTIUM COMPOUND, METHOD OF MANUFACTURING THIN FILM CONTAINING STRONTIUM AND SEMICONDUCTOR DEVICE USING THE SAME

(71) Applicant: SAMSUNG ELECTRONICS CO., LTD., Suwon-si (KR)

(72) Inventors: Jong Won CHOI, Suwon-si (KR); Dmitry KRAVCHUK, Suwon-si (KR); YONGSUK CHO, Suwon-si (KR); Kijung Jung, Suwon-si (KR); Joonghee Won, Suwon-si (KR); Chul BAIK, Suwon-si (KR); Hwea Yoon KIM, Suwon-si (KR); Seung-Yeon KWAK, Suwon-si (KR); Jung Im HAN, Suwon-si (KR); Tae Jin CHOI, Suwon-si (KR); YOUNGJAE PARK, Suwon-si (KR)

(21) Appl. No.: 19/411,665

(22) Filed: Dec. 8, 2025

(30) Foreign Application Priority Data
Dec. 9, 2024 (KR) 10-2024-0182020

(51) Int. Cl. C07F 3/00; C23C 16/40; C23C 16/455; H10D 1/00; H10D 30/01; H10P 14/60; H10P 14/692

(52) U.S. Cl. CPC C07F 3/00; C23C 16/404; C23C 16/45553; H10P 14/6339; H10P 14/69398; H10D 1/041; H10D 30/027

(57) ABSTRACT

A strontium compound, a method of making a thin film with the strontium compound, and a method of manufacturing a semiconductor device including the thin film.

The strontium compound is represented by Chemical Formula 1:

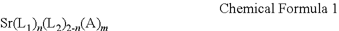

In Chemical Formula 1, n, L₁, L₂, A, and m are as defined herein.

### CROSS-REFERENCE TO RELATED APPLICATION

This application claims priority to Korean Patent Application No. 10-2024-0182020 filed on Dec. 9, 2024, and all the benefits accruing therefrom under 35 U.S.C. § 119, the content of which in its entirety is herein incorporated by reference.

### BACKGROUND

### 1. Field

The present disclosure relates to a strontium compound, a method of forming a thin film including a strontium-containing oxide, a method of manufacturing a semiconductor device including the thin film, and a semiconductor device including the thin film.

### 2. Description of the Related Art

Strontium or an oxide including strontium (for example, a strontium titanate (SrTiO₃)) may be utilized, for example, in the form of a nanoscale thin film, for example, as a material (for example, a high dielectric constant material) in various semiconductor devices or microelectronic devices. Formation of the thin film including strontium or an oxide including strontium may be carried out by various methods, for example, by a chemical vapor deposition (CVD) method or an atomic layer deposition (ALD) method. Accordingly, there is interest to develop strontium-containing compounds that may be used in the preparation of thin films as well as the use of such films in electronic devices.

### SUMMARY

An embodiment relates to a compound containing strontium, for example, useful for thin film deposition.

An embodiment relates to a strontium compound (as a precursor) or a composition including the strontium compound for forming a strontium-containing thin film.

An embodiment relates to a method of manufacturing a strontium-containing thin film using the strontium compound.

An embodiment relates to a method of manufacturing a semiconductor device using the strontium compound.

In an embodiment, the strontium compound is represented by Chemical Formula 1:

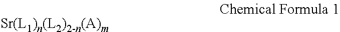

In Chemical Formula 1,
L₁ is a first ligand represented by Chemical Formula 2,
L₂ is a second ligand different from the first ligand,
A is a third ligand including oxygen or nitrogen,
n is 1 or 2, and
m is 0, 1, 2, 3, or 4,

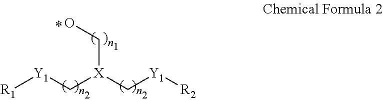

In Chemical Formula 2,
X is nitrogen or CR, where R of CR is hydrogen or a substituted or unsubstituted C1 to C10 alkyl group,
* is hydrogen or a binding site to strontium (Sr),
n₁ is 1 or 2,
each n₂ is independently 1, 2, or 3,
each Y₁ is the same or different and is independently O or NR, where R of NR is hydrogen or a substituted or unsubstituted C1 to C10 alkyl group, and
R₁ and R₂ are each independently a substituted or unsubstituted C1 to C5 alkyl group or a Si-containing organic group.

In an embodiment, in the Chemical formula 1, n may be 2.

The second ligand may include or may not include a substituted or unsubstituted (e.g., C1-C10) alkyl group, a substituted or unsubstituted (e.g., C1-C10) alkoxy group, a substituted or unsubstituted acetylacetonate group, a substituted or unsubstituted β-diketonate moiety, a substituted or unsubstituted ketoiminate (e.g., β-ketoiminate) moiety, a substituted or unsubstituted ketostearate (e.g., β-ketostearate) moiety, a substituted or unsubstituted diiminate (e.g., β-diiminate) moiety, a carbonyl group, a substituted or unsubstituted alkyl carbonyl group, a substituted or unsubstituted acetoxy group, a substituted or unsubstituted dialkylamido group, a substituted or unsubstituted acetamidinate group, a substituted or unsubstituted phenanthroline group, a substituted or unsubstituted glyoximate group, a substituted or unsubstituted carbamato group, a substituted or unsubstituted cyclopentadienyl group, a substituted or unsubstituted pyrrolyl group, a substituted or unsubstituted alkoxide group, a substituted or unsubstituted amidinate group, a substituted or unsubstituted imidazolyl moiety, a trispyrazolyl borate moiety, or a mixture thereof.

The first ligand may be represented by Chemical formula 2-1 or Chemical formula 2-2.

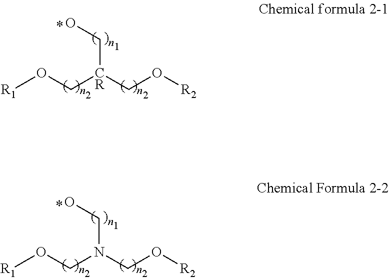

In Chemical Formula 2-1 or Chemical Formula 2-2,
* is hydrogen or a binding site to strontium,
n₁ is 1 or 2,
n₂ is independently 1, 2, or 3,
R of CR is hydrogen or a substituted or unsubstituted C1 to C10 alkyl group,
R₁ and R₂ are each independently a substituted or unsubstituted C1 to C5 alkyl group, or a Si-containing organic group.

The first ligand may be represented by Chemical Formula 2-3 or Chemical Formula 2-4:

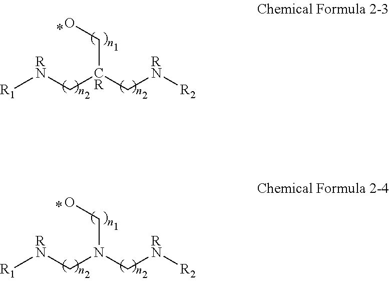

In Chemical Formula 2-3 or Chemical Formula 2-4,
* is hydrogen or a binding site to strontium,
n₁ is 1 or 2,
n₂ is independently 1, 2, or 3,
R of CR and NR are the same or different, and each R is independently hydrogen or a substituted or unsubstituted C1 to C10 alkyl group,
R₁ and R₂ are each independently a substituted or unsubstituted C1 to C5 alkyl group, or a Si-containing organic group.

The third ligand including oxygen or nitrogen may include or may not include a dialkoxyalkane such as dimethoxyethane, a tetrahydrofuran (THF), pyridine, a dialkyl ether such as diethyl ether, or a combination thereof.

The strontium compound may include or may not include the dimethoxyethane, THF, pyridine, diethyl ether, or a combination thereof.

The strontium compound may include or may not include the third ligand containing oxygen or nitrogen.

The strontium compound may be represented by any of the following formulae.

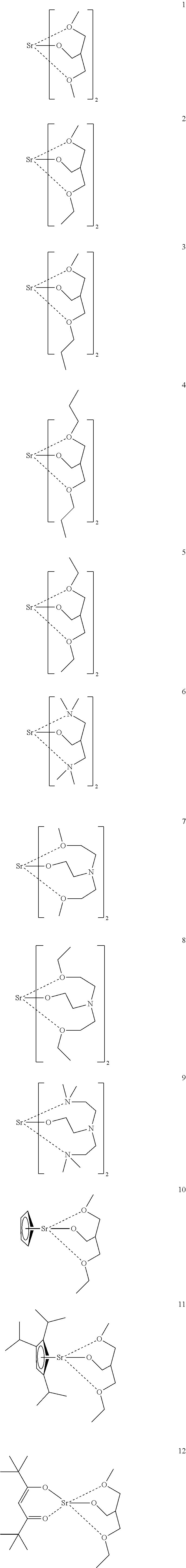

The strontium compound may exhibit a liquid state at a temperature greater than or equal to about 20° C. and less than or equal to about 50° C. (e.g., greater than or equal to about 20° C. and less than or equal to about 30° C.).

The strontium compound may have a molecular weight that is greater than or equal to about 150 g/mol, or greater than or equal to about 300 g/mol, and less than or equal to about 1,000 g/mol, or less than or equal to about 600 g/mol. For example, the strontium compound may have a molecular weight that is greater than or equal to about 150 g/mol and less than or equal to about 600 g/mol.

As confirmed by a thermogravimetric analysis, the strontium compound may have a temperature at which a weight reduction corresponds to 10% of a total weight of the compound (i.e., T₉₀%) that is greater than or equal to about 100° C. As confirmed by a thermogravimetric analysis, the strontium compound may have a temperature at which a weight reduction corresponds to 10% of the total weight of the compound (T₉₀%) that is less than or equal to about 205° C., less than or equal to about 200° C., less than or equal to about 190° C., less than or equal to about 170° C., or less than or equal to about 150° C. For example, the strontium compound may have a temperature at which a weight reduction corresponds to 10% of a total weight of the compound (i.e., T₉₀%) that is greater than or equal to about 100° C. and less than or equal to about 170° C.

As confirmed by a thermogravimetric analysis, the strontium compound may have a temperature at which a weight reduction corresponds to 50% of the total weight of the compound (T₅₀%) that is greater than or equal to about 150° C., or greater than or equal to about 180° C. As confirmed by a thermogravimetric analysis, the strontium compound may have a temperature at which a weight reduction corresponds to 50% of the total weight of the compound (T₅₀%) that is less than about 250° C., less than or equal to about 220° C., or less than or equal to about 200° C. For example, the strontium compound may have a temperature at which a weight reduction corresponds to 50% of a total weight of the compound (i.e., T₅₀%) that is greater than or equal to about 150° C. and less than or equal to about 220° C., for example, greater than or equal to about 150° C. and less than or equal to about 200° C.

As confirmed by a thermogravimetric analysis, the strontium compound may have a weight reduction in a temperature range of greater than or equal to about 250° C. and less than or equal to about 400° C., that is less than or equal to about 10% by weight, or less than or equal to about 8% by weight, based on the total weight of the compound.

In an embodiment, a composition for forming a strontium-containing thin film includes the strontium compound. The composition may further include or may not include an organic solvent. The organic solvent may be an inert solvent that does not react with the strontium compound.

The organic solvent may include, for example, a substituted or unsubstituted aliphatic hydrocarbon (e.g., alkane, alkene, or alkyne) solvent, a substituted or unsubstituted aromatic hydrocarbon solvent, a glyme, a polyamine solvent, or a combination thereof.

In an embodiment, a method of forming an oxide thin film includes performing a strontium cycle to form a strontium oxide (also referred to as strontium-containing oxide) or to obtain a thin film including a strontium-containing oxide.

The strontium cycle includes:
supplying (e.g., by pulsing) a gas including a strontium precursor gas into a chamber (e.g., a process chamber) including a substrate;
supplying an inert gas into the chamber to purge an excess of the strontium precursor gas from the chamber (e.g., using an inert gas);
supplying (e.g., pulsing) a co-reactant into the chamber; and
optionally providing an inert gas into the chamber to purge an excess of the co-reactant from the chamber (e.g., using an inert gas).

The strontium precursor gas includes the strontium compound according to an embodiment.

The method may further include performing a first metal cycle to form a first metal oxide. The first metal cycle includes:
supplying a gas including a first metal precursor (gas) into the chamber;
supplying an inert gas into the chamber to purge an excess of the first metal precursor (gas) from the chamber (e.g., using an inert gas);
supplying a first co-reactant for reaction with the first metal precursor (gas) into the chamber; and
optionally supplying an inert gas into the chamber to purge an excess of the first co-reactant from the chamber. The first metal precursor may include titanium, barium, ruthenium, or a combination thereof.

The method may include a plurality of the strontium cycles, for example, greater than or equal to about 2 times (cycles) and less than or equal to about 500 times (cycles).

The method may include a plurality of first metal cycles, for example, greater than or equal to about 2 times (cycles) and less than or equal to about 500 times (cycles).

In the method, the strontium cycle and the first metal cycle may be repeated in a predetermined order, or alternately.

The co-reactant may include a water vapor, oxygen, ozone, hydrogen peroxide, hydrogen, or a combination thereof.

The inert gas may include nitrogen gas, argon gas, helium gas, or a combination thereof.

In an embodiment, a method of manufacturing a semiconductor device includes:
providing (e.g. forming) a transistor integrated in or disposed on a semiconductor substrate, and
providing (e.g. forming) a capacitor electrically connected to the transistor,
wherein at least one of the providing (e.g. forming) of the transistor or providing (e.g. forming) the capacitor includes forming the above-described oxide thin film.

The oxide thin film may include a strontium oxide. The oxide thin film or the strontium oxide may further include a first metal. The first metal may include titanium, barium, ruthenium, or a combination thereof.

The oxide thin film or the strontium oxide may include a strontium titanate (e.g., SrTiO₃), a lanthanum strontium titanate, a barium strontium titanate (e.g., BaₓSr₁₋ₓTiO₃, wherein 0<x<1), or a combination thereof.

The oxide thin film may include a high dielectric constant material.

The formation of the capacitor may include providing a first electrode, forming the oxide thin film, and providing a second electrode.

The formation of the transistor may include forming a trench in the semiconductor substrate, forming the oxide thin film in the trench, and forming a gate conductor on the oxide thin film.

In an embodiment, a semiconductor device includes a semiconductor substrate, a transistor integrated in or disposed on the semiconductor substrate, and a capacitor electrically connected to the transistor, wherein at least one of the transistor or the capacitor includes a strontium-containing oxide thin film (also referred to as a thin film including a strontium-containing oxide) formed by the method described herein.

A strontium compound of an embodiment may exhibit a liquid state at a predetermined temperature, for example, at a temperature from room temperature to about 50° C., and may exhibit a relatively high vapor pressure.

In addition, when used in a deposition process (e.g., an atomic layer deposition process), the strontium compound may provide process stability and may contribute to realizing mass production of a device including a strontium-containing material thin film having a desired composition.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a flowchart of a strontium cycle for a method of forming a strontium material or a strontium-containing (oxide) thin film according to an embodiment.

FIG. 2 illustrates a flowchart of a first metal cycle in a method of forming a strontium material or a strontium-containing (oxide) thin film of an embodiment.

FIG. 3 is a cross-sectional view of a semiconductor device according to an embodiment.

FIG. 4 is a cross-sectional view of a semiconductor device according to an embodiment.

### DETAILED DESCRIPTION

Advantages and characteristics of this disclosure, and a method for achieving the same, will become evident referring to the following exemplary embodiments together with the drawings attached hereto. However, this invention may, be embodied in many different forms, the embodiments should not be construed as being limited to the embodiments set forth herein. Rather, these embodiments are provided so that this disclosure will be thorough and complete, and will fully convey the scope of the invention to those skilled in the art. Like reference numerals refer to like elements throughout.

In order to clearly explain the present disclosure, parts irrelevant to the description are omitted, and the same reference numerals are assigned to the same or similar elements throughout the specification. In the drawings, the thickness of layers, films, panels, regions, etc., are exaggerated for clarity. And in the drawings, for convenience of description, the thickness of some layers and regions are exaggerated. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion and does not necessarily mean “above”.

It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as being limited to “a” or “an.” “Or” means “and/or.”

As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the specification, the term “in cross-section” refers to a view of a cross-section obtained by cutting the relevant portion generally perpendicularly (e.g., substantially perpendicularly with respect to the bottom surface) and observing laterally it from the side.

Unless otherwise defined, all terms (including technical and scientific terms) used herein have the same meaning as commonly understood by one of ordinary skill in the art to which this disclosure belongs. It will be further understood that terms, such as those defined in commonly used, e.g., non-technical, dictionaries, should be interpreted as having a meaning that is consistent with their meaning in the context of the relevant art and the present disclosure, and will not be interpreted in an idealized or overly formal sense unless expressly so defined herein.

As used herein, when a definition is not otherwise provided, “substituted” refers to replacement of at least one hydrogen of a compound or a group with a corresponding substituent including a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heterolaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including (e.g., consisting of) carbon and hydrogen (e.g., alkyl, alkenyl, alkynyl, or aryl group). The hydrocarbon group may be a monovalent group or a group having a valence of greater than one formed by removal of one or more hydrogen atoms from an alkane, an alkene, an alkyne, or an arene. In the hydrocarbon or hydrocarbon group, at least one methylene may be replaced by an oxide moiety (—O—), a carbonyl moiety (—C(═O)—), an ester moiety (—C(═O)O—), —NH—, or a combination thereof. Unless otherwise stated to the contrary, the hydrocarbon or the hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl hexyl, etc.). In an embodiment, an alkyl group may have from 1 to 50 carbon atoms, or 1 to 18 carbon atoms, or 1 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 2 to 18 carbon atoms, or 2 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “aryl” refers to a group having a carbocyclic aromatic system. When the aryl group includes a plurality of rings, the plurality of rings may be fused to each other. Examples include a phenyl group and a naphthyl group. In an embodiment, an aryl group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, P, Si, B, Se, Ge, Te, S, or a combination thereof.

As used herein, “heteroaryl” refers to an aromatic group having at least one N, O, P, Si, B, Se, Ge, Te, S, or a combination thereof as a ring forming atom. Examples of heteroaryl groups include a pyridinyl group, a pyrimidinyl group, a pyrazinyl group, a pyridazinyl group, a triazinyl group, a quinolinyl group, and an isoquinolinyl group. When the heteroaryl group includes a plurality of rings, the plurality of rings may be fused to each other. In an embodiment, the heteroaryl group may have 3 to 50 carbon atoms, or 6 to 18 carbon atoms, or 6 to 12 carbon atoms.

As used herein, when a definition is not otherwise provided, “alkoxy” refers to an alkyl group linked to oxygen (e.g., alkyl-O—) for example, a methoxy group, an ethoxy group, or a sec-butyloxy group.

The term “cycloalkyl group” as used herein refers to a monovalent monocyclic saturated hydrocarbon group. Examples thereof include a cyclopropyl group, a cyclobutyl group, a cyclopentyl group, a cyclohexyl group, and a cycloheptyl group. In an embodiment, the cycloalkyl group may have 3 to 50 carbon atoms, or 3 to 18 carbon atoms, or 3 to 12 carbon atoms.

The term “heterocycloalkyl group” as used herein refers to a monovalent monocyclic group including at least one N, O, P, Si, B, Se, Ge, Te, S, or a combination thereof as a ring-forming atom in addition to the carbon atoms that are ring-forming atoms. Examples thereof include a tetrahydrofuranyl group and a tetrahydrothiophenyl group. In an embodiment, the heterocycloalkyl group may have 2 to 50 carbon atoms, or 2 to 18 carbon atoms, or 2 to 12 carbon atoms.

The term “cycloalkenyl group” as used herein refers to a monovalent monocyclic hydrocarbon group that has at least one carbon-carbon double bond in its ring, wherein the molecular structure as a whole is non-aromatic. Examples thereof include a cyclopentenyl group, a cyclohexenyl group, and a cycloheptenyl group. In an embodiment, the cycloalkenyl group may have 3 to 50 carbon atoms, or 3 to 18 carbon atoms, or 3 to 12 carbon atoms.

The term “heterocycloalkenyl group” as used herein refers to a monovalent monocyclic group including at least one N, O, P, Si, B, Se, Ge, Te, S, or a combination thereof as a ring-forming atom, and at least one double bond in its ring, wherein the molecular structure as a whole is non-aromatic. Examples of the heterocycloalkenyl group include a 2,3-dihydrofuranyl group and a 2,3-dihydrothiophenyl group. In an embodiment, the heterocycloalkenyl group may have 2 to 50 carbon atoms, or 2 to 18 carbon atoms, or 2 to 12 carbon atoms.

The term “arylalkyl group” refers to an alkyl group substituted with an aryl group. An example of an arylalkyl group is a benzyl group (i.e., —CH₂-phenyl).

The term “alkylaryl group” refers to an aryl group substituted with an alkyl group. An example of an alkylaryl group is a tolyl group.

As used herein, when a definition is not otherwise provided, “amine” is a compound represented by NR₃, wherein each R is independently hydrogen, a C1-C12 alkyl group, a C7-C20 alkylaryl group, a C7-C20 arylalkyl group, or a C6-C18 aryl group.

Unless mentioned to the contrary, a numerical range recited herein is inclusive. Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to a value” “at least value” or a “less than or equal to a value” or recited with “from a value” or “to a value”) may be used to form a numerical range of a given feature. In other words, the upper and lower endpoints set forth for various numerical values may be independently combined to provide a range.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5%, 3%, or 1% of the stated value.

In an embodiment, a strontium precursor for a process (e.g., a chemical vapor deposition method) for forming a Sr-containing thin film (e.g., a thin film including a strontium containing oxide) is provided. In an embodiment, the strontium precursor may be a Sr organometallic compound or a Sr coordination compound (e.g., a complex). The strontium precursor of an embodiment may exhibit improved volatility, a relatively low melting point, and/or a relatively high thermal stability, and is a raw material (precursor) suitable for thin film formation in a semiconductor manufacturing process.

In an embodiment, the strontium compound may be an organometal complex compound including an organic group (e.g., a ligand) and strontium.

The strontium compound may be represented by Chemical Formula 1:

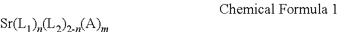

In Chemical formula 1,
L₁ is a first ligand represented by Chemical Formula 2,
L₂ is a second ligand different from the first ligand (e.g., a monoanionic ligand),
A is a third ligand including oxygen or nitrogen,
n is 1 or 2, and
m is 0 to 4.

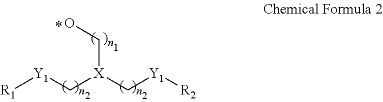

In Chemical Formula 2, X is nitrogen or CR (where R in CR is hydrogen or a substituted or unsubstituted C1 to C10 alkyl group, for example, methyl, ethyl, propyl, isopropyl, or butyl, pentyl, hexyl, or the like),
* is hydrogen or a binding site to strontium (Sr),
n₁ is 1 or 2,
each n₂ is independently 1 to 3 (for example, 1, 2, or 3),
each Y₁ of NR is the same or different and is each independently oxygen or NR (wherein R is hydrogen or a substituted or unsubstituted C1 to C10 alkyl group, for example, methyl, ethyl, propyl, isopropyl, butyl, or pentyl),
R₁ is a substituted or unsubstituted C1 to C5 alkyl group (for example, methyl, ethyl, propyl, isopropyl, butyl, isobutyl, pentyl or isopentyl group), or a Si-containing organic group (for example, a trialkylsilyl group such as Si(CH₃)₃), and
R₂ is a substituted or unsubstituted C1 to C5 alkyl group (for example, methyl, ethyl, propyl, isopropyl, butyl, isobutyl, pentyl or isopentyl group), or a Si-containing organic group (for example, a trialkylsilyl group such as Si(CH₃)₃). R₁ and R₂ can be the same or different.

An oxide film including strontium may have a perovskite structure exhibiting paraelectric properties. In an embodiment, a strontium oxide (e.g., SrTiO₃) thin film deposited by an atomic layer deposition (ALD) may achieve a dielectric constant of about 150 or greater and may exhibit a step coverage having a desired degree of thickness and a desired degree of composition within a pattern. Therefore, various thin films containing Sr (for example, a SrTiO₃-containing thin film) may be applicable as materials having a high dielectric constant in, for example, next-generation DRAM capacitors.

The formation of the thin film may be implemented by various methods, for example, a sputtering process, an ion plating process, a thermal decomposition process, a sol-gel process, a metal-organic deposition (MOD) process, or a chemical vapor deposition (CVD) process. The ALD (atomic layer deposition) or chemical vapor deposition process may be utilized for semiconductor device fabrication in terms of compositional controllability, step coverage, mass productivity, and hybrid integration capability. Few precursor materials for Sr atom sources that can be used in the chemical vapor deposition have been reported, but these compounds suffer a problem in that the deposition process cannot be stably operated due to the low volatility, high melting point, and low thermal stability of the compounds of the strontium, which belongs to the alkaline earth metal group.

For example, Sr(iPr₃Cp)₂ (bis(1,2,4-tri-isopropylcyclopentadienyl) strontium) has been relatively widely used as a strontium precursor. Although Sr(iPr₃Cp)₂ can achieve a vapor pressure for deposition by heating a canister to about 100° C., it has high reactivity, which may cause concern for excessive initial growth. In addition, Sr(iPr₃Cp)₂ is in a solid phase within a temperature range from room temperature to about 50° C., which may make it difficult to provide a desired level of conformality within a high aspect ratio DRAM capacitor structure.

In the related art, the types of strontium-containing raw materials or precursors that can be used in deposition processes are limited, and there are some difficulties in performing deposition processes using such materials. Most of the strontium precursors available in the related art are solid-phase materials having very low vapor pressure. In order for such strontium precursors to provide a desired level of vapor pressure in a process, it may be necessary to heat a canister and a line to relatively high temperatures, which may require the use of a high-temperature canister and high-temperature valves (v/v), or alternatively, may require a liquid delivery system (LDS) method involving solvent dissolution. The present inventors have found that the strontium precursors of the related art may have problems of contamination caused by condensation of the precursor within a cold spot or valve (v/v), making maintenance of the process or equipment difficult.

For example, Sr(iPr₃Cp)₂ can obtain a vapor pressure suitable for deposition by heating the canister to about 100° C.; however, it has high reactivity, raising concerns regarding excessive initial growth. The present inventors have also found that Sr(iPr₃Cp)₂ may be in a solid phase under desired deposition conditions and may have difficulties in providing a desired level of conformality within a high aspect ratio DRAM capacitor structure. In addition, moderate reactivity of a strontium precursor is desirable in terms of suppressing excessive initial growth and achieving a low impurity content.

The molecular size of the strontium precursor may need to be controlled for step coverage and applicability to mass production. Therefore, at present, the ALD process using strontium precursors is a highly challenging process. Furthermore, from the viewpoint of mass productivity, the development of strontium precursors in a liquid phase or having sufficient vapor pressure, as well as the development of an ALD process using such precursors, is desirable.

A strontium compound according to an embodiment may address on or more of the processing technical issues stated above. The strontium compound of an embodiment may exhibit a liquid phase at a temperature of about 20° C. to about 50° C. or about 25° C. to about 35° C. (for example, at room temperature). In addition, as confirmed from thermogravimetric analysis results, it is expected to provide a desired level of vapor pressure in semiconductor device fabrication processes (for example, a thin film deposition process or an ALD process).

In an embodiment, the first ligand may have two or more oxygen atoms, together with the oxygen atom directly bonded to strontium. In addition to being directly bonded to the strontium (for example, via covalent bond) (see the O bearing *), the oxygen atoms (corresponding to the O in Y₁) may have additional interactions with strontium (e.g., interacting with strontium via lone pair of electrons, thereby forming coordinate bonds), contributing to increased metal coverage by the ligand. In an embodiment, the first ligand may be represented by Chemical Formula 2-1 or Chemical Formula 2-2:

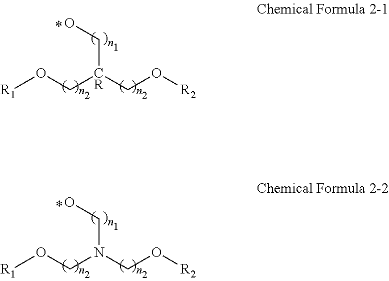

In Chemical Formula 2-1 or Chemical Formula 2-2,
* denotes hydrogen or a binding site to strontium,
n₁ is 1 or 2,
R of CR is a hydrogen or a substituted or unsubstituted C1 to C10 alkyl group, and
each n₂ is independently 1 to 3 (for example, 1, 2, or 3).
R₁ may be a substituted or unsubstituted C1 to C5 alkyl group (for example, methyl, ethyl, propyl, isopropyl, butyl, isobutyl, pentyl, or isopentyl) or a Si-containing organic group.
R₂ may be a substituted or unsubstituted C1 to C5 alkyl group (for example, methyl, ethyl, propyl, isopropyl, butyl, isobutyl, pentyl, or isopentyl) or a Si-containing organic group. R₁ and R₂ may be the same or different. It will be understood that, when propyl and isopropyl are mentioned in parallel, the “propyl” can mean “n-propyl”, and when butyl and isobutyl are mentioned in parallel, the “butyl” can means “n-butyl”. when pentyl, and isopentyl are mentioned in parallel, the “pentyl” can means “n-pentyl”.

In the first ligand having such a structure, an oxygen atom may be bonded to a strontium atom through a covalent bond or may interact with the strontium atom by via a lone pair of electrons (e.g., forming coordinate bonds).

In an embodiment, the first ligand may include two, three, or more nitrogen atoms, and the nitrogen atoms (N in Y₁) may have additional interactions with strontium (e.g., interacting with strontium via lone pair of electrons, thereby forming a coordinate bond), contributing to increased metal coverage by the ligand. In an embodiment, the first ligand may be represented by Chemical Formula 2-3 or Chemical Formula 2-4:

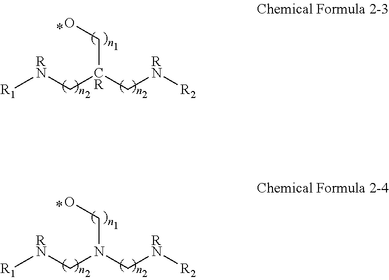

In Chemical Formula 2-3 or Chemical Formula 2-4,
* denotes hydrogen or a binding site to strontium,
n₁ is 1 or 2,
each n₂ is independently 1 to 3 (for example, 1, 2, or 3).
R of CR and NR is a hydrogen or a substituted or unsubstituted C1 to C10 alkyl group, and
R₁ may be a substituted or unsubstituted C1 to C5 alkyl group (for example, methyl, ethyl, propyl, isopropyl, butyl, isobutyl, pentyl or isopentyl) or a Si-containing organic group, and
R₂ may be a substituted or unsubstituted C1 to C5 alkyl group (for example, methyl, ethyl, propyl, isopropyl, butyl, isobutyl, pentyl or isopentyl) or a Si-containing organic group. R₁ and R₂ may be the same or different.

In the first ligand having such a structure, a nitrogen atom may interact with the strontium atom via a lone pair of electrons (e.g., forming coordinate bonds).

In an embodiment, in the strontium compounds described herein, the Si-containing organic group may be, for example, an alkylsilyl group having one or more, two or more, or three or more substituted or unsubstituted C1-C10 or C2-C3 alkyl groups, such as methyl, ethyl, or propyl groups. Examples thereof include a substituted or unsubstituted trimethylsilyl group, a substituted or unsubstituted triethylsilyl group, and a substituted or unsubstituted diethylmethylsilyl group, but are not limited thereto.

As noted, in the above chemical formulas, R₁ may be the same as or different from R₂. In R₁ and R₂, the C1 to C5 alkyl group may be substituted with a halogen group, an amino group, a hydroxy group, an alkoxy group, or the like, but is not limited thereto.

A strontium compound according to an embodiment may include, as a ligand, a first ligand having the structure described herein in the manner described herein. For example, in Chemical Formula 2 for the first ligand, n₁, within the defined range, may ensure an appropriate distance between strontium and the first ligand, thereby providing increased shielding or metal coverage for strontium and reducing interaction between final precursor molecules.

In addition, in the first ligand of Chemical Formula 2, the introduction of a flexible alkyl group may increase entropy, and a non-conjugate type structure may minimize intermolecular interactions. The first ligand of Chemical Formula 2 includes a lone pair of electrons, which may increase metal coverage by the ligand and contribute to stabilization of the strontium atom.

In the case of strontium precursors of the related art, due to the large size of the strontium atom, interactions between precursor molecules may readily occur, causing the molecules to exist as dimers or oligomers, which may result in an increase in the melting point and viscosity of the precursor compound and a decrease in vapor pressure.

In a strontium precursor according to an embodiment, the inclusion of the first ligand in the manner described herein may contribute to improved metal coverage of the ligand, enhanced precursor stability, and reduced interaction between strontium precursors.

Accordingly, the strontium compound of an embodiment having such a structure may exist in a liquid state at a predetermined temperature (for example, a temperature from room temperature to about 50° C.) without any special treatment. In addition, for example, as confirmed by thermogravimetric analysis or other suitable analysis means, the strontium compound of an embodiment is expected to provide a higher level of vapor pressure than strontium precursors of the related art under thin film deposition process conditions.

Strontium has a relatively large atomic size. Without wishing to be bound by any theory, it is believed that this large size of strontium, which is an alkaline earth metal, may cause significant intermolecular interaction between precursor molecules even in the presence of ligand coordination, which may lead to an increase in melting point, an increase in viscosity, and a decrease in vapor pressure. Therefore, ligands according to the related art may have difficulty in sufficiently coordinating to such strontium atoms to provide desired characteristics.

In contrast, in case of the strontium compound of an embodiment, the introduction of the first ligand may reduce intermolecular interaction between strontium precursors to a desired level by sufficiently shielding the central atom, strontium, and thereby may achieve an increase in precursor vapor pressure and liquefaction. The introduction of the first ligand may result in an increase in the metal (Sr) coverage of the central metal, i.e., strontium, in the precursor.

In an embodiment, in Chemical Formula 1, n may be 2, and in this case, the strontium compound may include the first ligand without a second ligand.

The strontium compound of an embodiment may have one or more, for example, two first ligands. In an embodiment, the strontium compound may further include a second ligand different from the first ligand. The second ligand may be a monoanionic ligand having a chemical structure different from that of the first ligand. The strontium precursor of an embodiment may include or may not include the second ligand (n is 2).

The second ligand may include a substituted or unsubstituted alkyl group, a substituted or unsubstituted alkoxy group, a substituted or unsubstituted acetylacetonate group, a substituted or unsubstituted β-diketonate moiety (for example, a substituted or unsubstituted heptanedionate moiety, a substituted or unsubstituted acetylacetonate moiety, or a substituted or unsubstituted octanedionate moiety), a substituted or unsubstituted β-ketoiminate moiety (for example, aminopentenonato moiety), a substituted or unsubstituted β-ketostearate moiety, a substituted or unsubstituted β-diiminate moiety, a carbonyl group, a substituted or unsubstituted alkylcarbonyl group, a substituted or unsubstituted acetoxy group, a substituted or unsubstituted dialkylamido group, a substituted or unsubstituted acetamidinate group, a substituted or unsubstituted phenanthroline group, a substituted or unsubstituted glyoximate group, a substituted or unsubstituted carbamate group, a substituted or unsubstituted cyclopentadienyl group, a substituted or unsubstituted pyrrolyl group, a substituted or unsubstituted alkoxide group, a substituted or unsubstituted amidinate group, a substituted or unsubstituted imidazolyl moiety, a trispyrazolylborate moiety, or a combination thereof.

The second ligand may be represented by, but is not limited to, the following formula:

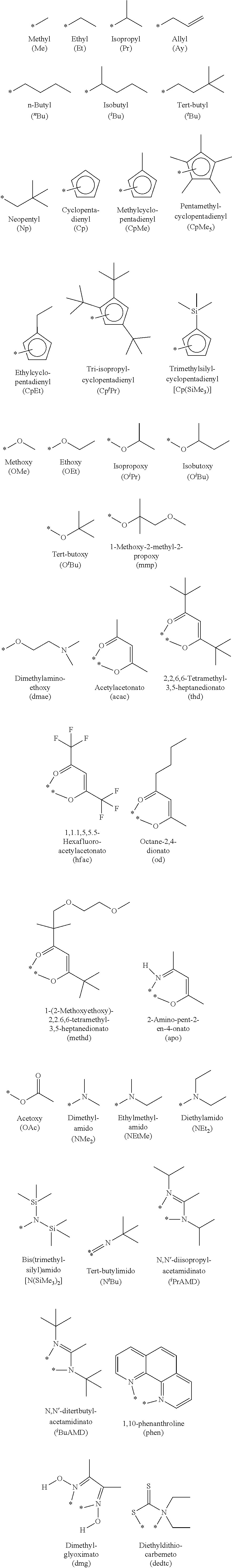

In the above formulas, * denotes a portion bonded to strontium.

In Chemical Formula 1, A is a third ligand including oxygen or nitrogen. The third ligand with oxygen or nitrogen may be introduced from a solvent or the like used during the synthesis process of the precursor (e.g. may be a solvate moiety). Such a third ligand may be removed through a post-synthesis removal process.

In an embodiment, the third ligand may include, but is not limited to, a dialkoxyalkane such as dimethoxyethane, tetrahydrofuran, pyridine, a dialkyl ether such as diethyl ether, or a combination thereof. The strontium compound of an embodiment may further include or may not include the third ligand. The strontium compound of an embodiment may include or may not include dimethoxyethane (glyme), THF, pyridine, diethyl ether, or a combination thereof.

In an embodiment, the strontium compound may be represented by one of the following formulae:

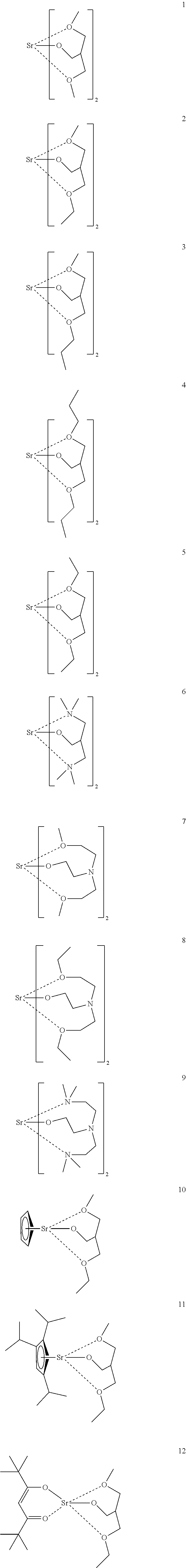

The strontium compound of an embodiment may exhibit reduced intermolecular interaction and may be in a liquid phase at room temperature, and therefore, may be useful as a strontium precursor in various deposition processes, e.g., supplied with or without a carrier gas. The strontium compound may exhibit a liquid state at a temperature greater than or equal to about 20° C. and less than or equal to about 50° C.

The strontium compound of an embodiment, as confirmed by thermogravimetric analysis, may have a temperature at which a 10% weight loss occurs (that is, a temperature at which the residual weight is 90%), T₉₀% that is greater than or equal to about 100° C.

The strontium compound may have a molecular weight greater than or equal to about 150 g/mol, greater than or equal to about 180 g/mol, greater than or equal to about 190 g/mol, greater than or equal to about 200 g/mol, greater than or equal to about 250 g/mol, greater than or equal to about 280 g/mol, greater than or equal to about 300 g/mol, greater than or equal to about 350 g/mol, greater than or equal to about 400 g/mol, greater than or equal to about 410 g/mol, greater than or equal to about 440 g/mol, or greater than or equal to about 450 g/mol. The strontium compound may have a molecular weight less than or equal to about 1,000 g/mol, less than or equal to about 800 g/mol, less than or equal to about 600 g/mol, less than or equal to about 550 g/mol, or less than or equal to about 500 g/mol.

As confirmed by a thermogravimetric analysis, the strontium compound may have a temperature at which the weight (mass) loss is 10% of the total weight of the compound (T₉₀%) that is greater than or equal to about 100° C., greater than or equal to about 120° C., greater than or equal to about 130° C., greater than or equal to about 140° C., or greater than or equal to about 150° C. The strontium compound may have a temperature at which the weight (mass) loss is 10% of the total weight of the compound (T₉₀%) that is less than or equal to about 205° C., less than or equal to about 200° C., less than or equal to about 190° C., less than or equal to about 180° C., less than or equal to about 170° C., less than or equal to about 160° C., or less than or equal to about 150° C.

As confirmed by thermogravimetric analysis, the strontium compound may have a temperature at which the mass loss is 50% of the total weight of the compound (T₅₀%) that is greater than or equal to about 150° C., greater than or equal to about 160° C., greater than or equal to about 170° C., greater than or equal to about 180° C., greater than or equal to about 185° C., or greater than or equal to about 190° C. The strontium compound may have a temperature at which the mass loss is 50% of the total weight of the compound (T₅₀%) that is less than about 250° C., less than or equal to about 240° C., less than or equal to about 230° C., less than or equal to about 220° C., less than or equal to about 215° C., less than or equal to about 210° C., less than or equal to about 205° C., or less than or equal to about 200° C.

As confirmed by thermogravimetric analysis, the strontium compound may have a slope defined by the following equation greater than or equal to about −2, greater than or equal to about −1.7, greater than or equal to about −1.5, greater than or equal to about −1.4, greater than or equal to about −1.3, greater than or equal to about −1.2, greater than or equal to about −1.1, and less than 0, or less than or equal to about −0.5:

Slope=dW/dT
where dW represents a change in weight and dT represents a change in temperature.

The slope may be the weight change per change in temperature, and a larger absolute value of slope may indicate that the corresponding strontium compound is more readily volatilized.

As confirmed by thermogravimetric analysis, the strontium compound may exhibit, a weight loss between a temperature greater than or equal to about 250° C. and less than or equal to about 400° C. that is less than or equal to about 10 wt %, less than or equal to about 9 wt %, less than or equal to about 8 wt %, less than or equal to about 7 wt %, less than or equal to about 6 wt %, less than or equal to about 5 wt %, less than or equal to about 4 wt %, less than or equal to about 3 wt %, less than or equal to about 2 wt %, less than or equal to about 1 wt %, or less than or equal to about 0.5 wt %, based on the total weight of the compound.

Without wishing to be bound by any theory, the strontium compound of an embodiment may exhibit, for example, a thermal behavior different from that of strontium precursors according to the related art, as confirmed by thermogravimetric analysis. This may indicate that the strontium compound of an embodiment exhibits a relatively reduced vaporization temperature, improved vapor pressure characteristics, and enhanced process stability. In an embodiment, the relatively low T₅₀% and T₉₀% values observed in the thermogravimetric analysis may indicate that the strontium compound of an embodiment exhibits higher volatility and thus increased vapor pressure.

The strontium compound of an embodiment may be suitably synthesized by adopting known chemical reactions involving commercially available reagents. For example, the strontium compound of an embodiment may be prepared by reacting a first reagent including a first ligand moiety and a reactive group, a second reagent including a second ligand moiety and a reactive group, and a strontium-containing reagent in an appropriate solvent. The synthesis method of the first reagent may be realized by those skilled in the art by referring to the method provided in the Preparation Examples, and the second reagent may be commercially available or easily obtained by known methods.

Examples of strontium-containing reagents may include Sr(HMDS)₂ (strontium bis[bis(trimethylsilyl)amide]) but are not limited thereto. The strontium-containing reagent may also be commercially available or easily synthesized by known methods.

The organic solvent may include, for example, a substituted or unsubstituted aliphatic hydrocarbon solvent (for example, an alkane such as hexane, octane, or heptane; an alkene; or an alkyne), a substituted or unsubstituted aromatic hydrocarbon solvent such as toluene, an ether solvent such as glyme, THF, or diethyl ether, pyridine, a polyamine solvent, or a combination thereof.

The strontium compound of an embodiment may exhibit a liquid state at a predetermined temperature (for example, at a temperature of about 20° C. to about 50° C.) and may exhibit an increased level of vapor pressure. Therefore, the strontium compound of an embodiment may be utilized in the formation of a thin film through a vapor-phase deposition process (for example, in forming an oxide or a high-dielectric-constant material thin film during semiconductor device fabrication).

Accordingly, an embodiment is directed to a method of manufacturing a thin film using the strontium compound.

In an embodiment, the thin film formation using the strontium compound may include a chemical vapor deposition (CVD) process or an atomic layer deposition (ALD) process. The chemical vapor deposition process uses a volatile compound, which may be vaporized and continuously introduced into a deposition chamber. The precursor compound may chemically react either in the vapor phase or directly on a heated substrate to form a film of the desired material, while an undesired volatile component may be removed by vacuum pumping or inert gas purging. In the case of CVD, a single-source precursor (SSP) or multiple-source precursors may be used to produce a desired material film. The strontium compound of an embodiment may be used in a chemical vapor deposition process to form a material thin film having a desired composition.

In an embodiment, the thin film formation using the strontium compound may involve an atomic layer deposition (ALD). In the method of an embodiment, the atomic layer deposition technique may involve two alternating surface reactions for the thin film formation.

In the ALD of the embodiment, the surface of a substrate may be sequentially exposed to a precursor and a co-reactant (reactant), and, if desired, the two surface reactions may be separated using an inert gas such as argon (Ar) or nitrogen (N₂). Once the surface of the substrate becomes saturated by exposure to the precursor (or co-reactant) in each step, no further reaction occurs.

Through such a self-limiting thin film growth mechanism, the method of an embodiment involving the ALD may achieve excellent conformality, uniform coverage, and precise thickness control. In the method of an embodiment, the ALD may proceed in a cyclic manner.

In an embodiment, a growth cycle (i.e., each of the growth cycles) may include an injection of the precursor; an exposure of the substrate to the precursor; a purging and exhausting to remove an excess of the precursor and a by-product; an injection of and exposure to the co-reactant; and a purging and exhausting to remove an excess of co-reactant and a by-product. In the method of an embodiment, the ALD or the growth cycle may repeat a predetermined number of cycles to deposit a desired film thickness. Accordingly, in the ALD technique, precise control of the film thickness may be achieved depending on the number of cycles. In an embodiment, the terms “excess of the precursor” and “excess of the co-reactant” may refer to a portion of the respective species remaining in the reaction space after completion of the self-limiting surface reaction, and may include unreacted gas-phase species, weakly physisorbed species, and/or volatile by-products.

The time required for one cycle may range from several seconds to several minutes depending on (1) the purpose of the process, (2) the chemical properties of the precursor used, (3) the structure of the substrate and the deposition temperature, and (4) the reactivity between the substrate and the precursor and is not particularly limited. Each cycle may be designed in consideration of the interaction between the precursor and the co-reactant as well as the geometrical characteristics of the substrate to be used.

Accordingly, in an embodiment, a method of forming an oxide thin film includes performing a strontium cycle to form a strontium oxide. The strontium cycle includes:
supplying (for example, pulsing) a gas including a strontium precursor (hereinafter, can be referred to as “strontium precursor gas”) into a chamber (for example, a process chamber) including a substrate (S101);
supplying an inert gas into the chamber to purge excess strontium precursor gas (for example, using an inert gas) (S102); and
supplying (for example, pulsing) a co-reactant into the chamber (S103).

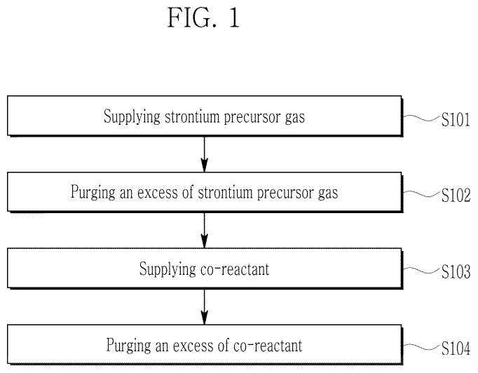

The strontium precursor gas or the strontium precursor includes a strontium compound according to an embodiment. An inert gas, may also be used or may not be used as a carrier gas in the supplying of the strontium precursor. The strontium precursor gas may be a gasified strontium compound according to an embodiment. In an embodiment, the strontium precursor gas may not include the inert gas. The method may further include supplying an inert gas into the chamber to purge excess co-reactant (for example, using an inert gas) (S104) (See FIG. 1).

The supply of the strontium precursor gas may be performed by an appropriate method known to those skill in the deposition art and is not particularly limited. The supply of the strontium precursor gas may include the use of a composition for thin film formation. In an embodiment, the composition for thin film formation includes the strontium compound. The composition may further include or may not include an organic solvent. The organic solvent may be an inert solvent that does not react with the strontium compound. The organic solvent is not particularly limited, and any of the solvents listed above as a reaction solvent may be used. In an embodiment, the organic solvent may include toluene, hexane, octane, or the like, but is not limited thereto.

The supply of the strontium precursor gas may include vaporizing the composition for thin film formation, which is stored in a container, by heating or by pressure reduction, to form a vapor and supplying the vapor to a chamber in which the substrate is placed. In an embodiment, the composition for thin film formation may be supplied in a liquid state to a vaporization chamber, and in the vaporization chamber, the composition may be vaporized by heating or pressure reduction to form a vapor that is then supplied to the chamber in which the substrate is placed.

The supply of the strontium precursor gas may be performed with an aid of a carrier gas. In an embodiment, a liquid precursor may be vaporized by bubbling a carrier gas through it, optionally under heating. Since the strontium compound (i.e., the precursor) of an embodiment is in a liquid state under conditions of the method of an embodiment, it may be advantageous for vaporization. The carrier gas may be appropriately selected and may include an inert gas such as nitrogen, argon, or helium.

The strontium precursor supplied into the chamber may react with and be adsorbed onto the substrate. When all reactive sites on the substrate are saturated with the strontium precursor, the remaining excess strontium precursor and a by-product may be removed in a subsequent purging step (S102).

Then, a co-reactant may be supplied (for example, pulsed) into the process chamber. The co-reactant reacts with the strontium precursor adsorbed on the substrate to form a thin film of a strontium-containing material (for example, a strontium oxide). In some embodiments including plasma enhancement, the co-reactant may be ignited by plasma.

Through the reaction with the co-reactant, all reactive sites on the surface of the substrate may be consumed, and at this time, the chamber may again be purged using an inert carrier gas (S104). Subsequently, it may be determined whether the thin film formed on the substrate has reached a desired thickness or composition, and if the desired thickness or composition has not been achieved, the strontium cycle may be repeated until the film formed on the substrate reaches the desired thickness.

The method may further include a first metal cycle for forming a first metal oxide. The first metal cycle includes:
supplying a gas including a first metal precursor (hereinafter, referred to as first metal precursor gas) into the chamber (e.g., process chamber) (S201);
supplying an inert gas into the chamber to purge excess first metal precursor (gas) (for example, using an inert gas) (S202); and
supplying a first co-reactant into the chamber to react with the first metal precursor (gas) (S203).

The first metal cycle may further include supplying an inert gas into the process chamber to purge excess first co-reactant (S204). The first metal precursor may include titanium, barium, ruthenium, or a combination thereof.

The type of the first metal precursor is not particularly limited and may be appropriately selected. The first metal precursor may include a metal alkoxide or an organometallic ammonium salt but is not limited thereto. When the first metal precursor includes titanium, the first metal precursor may include a titanium compound such as Ti(OiPr)₄, Ti(OtBu)₄, Ti(NMe₂)₄, Ti(NEtMe)₄, Ti(NEt₂)₄, but is not limited thereto. Herein, iPr means iso-propyl, tBu means t-butyl, Me means methyl, and Et means ethyl.

The preparation and supply of the gas of the first metal precursor may be carried out in reference to the description provided above for the strontium precursor.

The method may include a plurality of strontium cycles. The method may also include a plurality of first metal cycles. In the method, the strontium cycle and the first metal cycle may be alternately or sequentially repeated in a predetermined order, considering the composition of the thin film to be formed, but the sequence is not particularly limited.

The strontium compound of an embodiment and the thin film formation method using the same may be utilized in the manufacture of a semiconductor device (for example, a capacitor or a transistor), such as for forming a dielectric layer or an insulating layer.

Accordingly, in an embodiment, a method for manufacturing a semiconductor device includes:
providing or forming a transistor integrated into or disposed on a semiconductor substrate; and
providing or forming a capacitor electrically connected to the transistor,
wherein at least one of the providing (or forming) of the transistor or the providing (or forming) of the capacitor includes forming the above-described thin film (for example, a thin film containing a strontium material or a thin film containing a strontium oxide) in accordance with a deposition method described herein.

The oxide thin film may include a strontium oxide. The oxide thin film or the strontium oxide may further include a first metal. The first metal may include titanium, barium, ruthenium, or a combination thereof.

The oxide thin film or the strontium oxide may include strontium titanate (SrTiO₃), lanthanum strontium titanate, barium strontium titanate [BaₓSr₁₋ₓTiO₃ (where 0<x<1)], or a combination thereof.

The oxide thin film may include a high dielectric constant material.

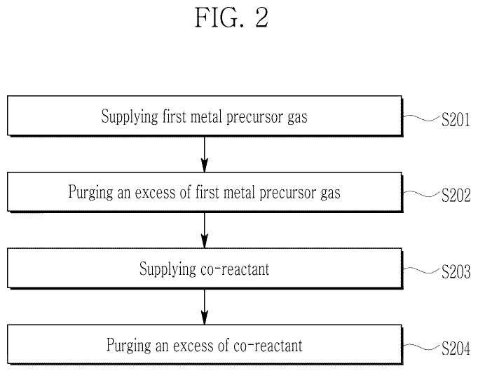

In a method for manufacturing a semiconductor device according to an embodiment, the forming of the capacitor may include forming or providing a first electrode, forming the oxide thin film, and forming or providing a second electrode. The formation of the oxide thin film (or the dielectric film) may be performed according to the thin film formation method described herein. The capacitor may be formed along the profile of the first electrode. The formation of the capacitor dielectric layer may refer to the flow charts of FIG. 1 and FIG. 2. A second electrode may be formed or provided on the formed capacitor dielectric layer. The methods of forming the first and second electrodes are not particularly limited and may be appropriately selected.

In an embodiment, forming the transistor may include forming a trench in a semiconductor substrate, forming the oxide thin film within the trench, and forming or providing a gate conductor on the oxide thin film. The formation of the oxide thin film (or gate insulating film) may be performed according to the thin film formation method described herein, for example, referring to FIG. 1 and FIG. 2.

In an embodiment, the semiconductor device includes a semiconductor substrate, a transistor integrated into or disposed on the semiconductor substrate, and a capacitor electrically connected to the transistor. At least one of the transistor or the capacitor includes a strontium-containing oxide thin film (for example, formed by the method described herein). The oxide thin film may be applied as a dielectric layer, insulating layer, passivation layer, and/or protective layer in various devices. The device may be, for example, a semiconductor device or a display device.

Hereinafter, an example of a semiconductor device according to an embodiment will be described with reference to the drawings.

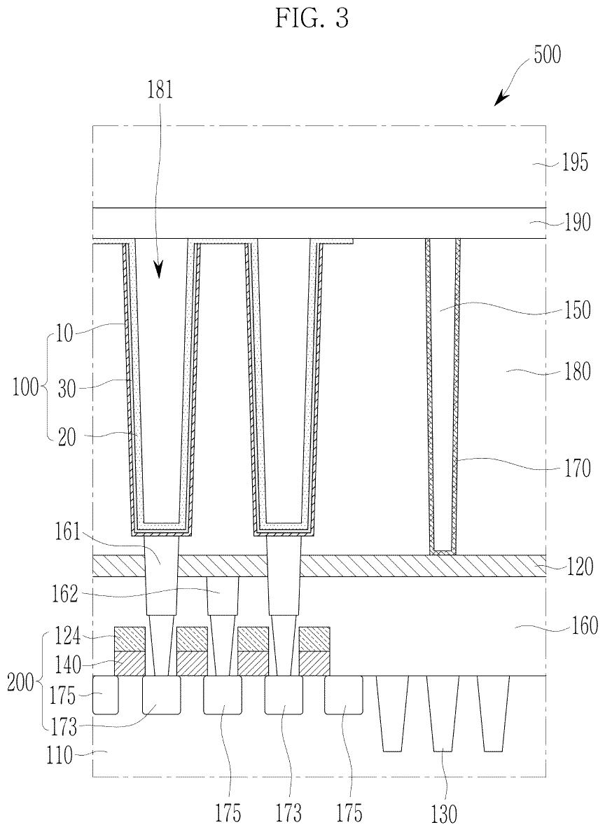

FIG. 3 is a cross-sectional view showing an example of a semiconductor device according to an embodiment.

Referring to FIG. 3, a semiconductor device 500 according to an embodiment includes a semiconductor substrate 110, a transistor 200, and a capacitor 100. At least one of the transistor 200 or the capacitor 100 may include an oxide film, and the oxide film may be formed by the above-described method. The oxide film may be, for example, a strontium oxide film.

The semiconductor substrate 110 may include silicon; germanium; silicon-germanium; a Group III-V compound such as GaP, GaAs, or GaSb; or a combination thereof. In an embodiment, the semiconductor substrate 110 may be a silicon-on-insulator (SOI) substrate or a germanium-on-insulator (GOI) substrate.

The transistor 200 may be located in an active region defined by a shallow trench isolation (STI) 130 in the semiconductor substrate 110 and may be electrically connected to a bit line 120 and the capacitor 100 to serve as a switching element. The transistor 200 may be a field effect transistor (FET) including a source region 173, a drain region 175, a gate electrode 124, and a gate insulating film 140. The field effect transistor (FET) may have various structures and, for example, may be a FinFET, GAAFET, MBCFET, CFET, or VFET, but is not limited thereto.

In an embodiment, the source region 173 and the drain region 175 are provided in the semiconductor substrate 110 and are disposed spaced apart from each other along an in-plane direction of the semiconductor substrate 110. The source region 173 and the drain region 175 may be conductive regions highly doped with a p-type or n-type impurity in the semiconductor substrate 110. In the case of an n-type transistor, the source region 173 and the drain region 175 may be highly doped with an n-type impurity, and in the case of a p-type transistor, the source region 173 and the drain region 175 may be highly doped with a p-type impurity. The source region 173 may be electrically connected to the capacitor 100, and the drain region 175 may be electrically connected to the bit line 120.

The gate electrode 124 may be formed on the semiconductor substrate 110 and may be located between the source region 173 and the drain region 175. The gate electrode 124 may include a low-resistance conductive material and, for example, may include Ti, TiN, TiON, or a combination thereof, but is not limited thereto. The gate electrode 124 may be formed as a single layer or as two or more layers.

The gate insulating film 140 may be located between the gate electrode 124 and the semiconductor substrate 110 and may include an oxide film in accordance with an embodiment described herein. The gate insulating film 140 may include the oxide film formed by the method of an embodiment involving the atomic layer deposition, and may be, for example, a strontium oxide film. A detailed description of the strontium oxide film is as described herein.

An interlayer insulating film 160, 180 may be formed over the transistor. The interlayer insulating film 160, 180 may include an oxide, nitride, oxynitride, or a combination thereof including, for example, silicon, aluminum, hafnium, lanthanum, zirconium, tantalum, yttrium, titanium, barium, strontium, or an alloy thereof, but is not limited thereto. The interlayer insulating film 160, 180 has a plurality of contact holes, and the contact holes are filled with a conductive material to form a plurality of contacts 161, 162, and 150.

A bit line 120 may be formed between the interlayer insulating films 160 and 180. The bit line 120 may be electrically connected to a drain region 175 of the transistor 200 through a contact 162. The bit line 120 may be disposed to intersect with a word line (not shown), and a plurality of arrays may be formed by the bit line 120 and the word line. The word line may be electrically connected to the gate electrode 124.

A capacitor 100 may be embedded in the interlayer insulating film 180 and, more specifically, may be formed in a trench 181 provided in the interlayer insulating film 180. The shape of the trench 181 is not particularly limited and, for example, a connection portion between a bottom surface and a side surface of the trench 181 may have a rounded shape, or the side surface of the trench 181 may be inclined at a predetermined angle. The trench 181 may have a high aspect ratio, and the higher the aspect ratio, the greater the capacitance of the capacitor 100. The capacitor 100 may be electrically connected to a source region 173 of the transistor 200 through a contact 161.

The capacitor 100 includes a first electrode 10, a dielectric film 30, and a second electrode 20.

The first electrode 10 may be located along an inner wall of the interlayer insulating film 180 within the trench 181. The first electrode 10 may be a thin film and, for example, may be a continuous thin film formed with a substantially uniform thickness along the inner wall of the interlayer insulating film 180 within the trench 181. For example, the first electrode 10 may be formed by atomic layer deposition (ALD).

The dielectric film 30 may include a thin film (for example, an oxide thin film or a strontium oxide thin film) formed by the thin film formation method described herein (for example, involving the atomic layer deposition). The oxide thin film or the strontium oxide thin film may include strontium titanate (SrTiO₃), lanthanum strontium titanate, barium strontium titanate [BaₓSr₁₋ₓTiO₃ (where 0<x<1)], or a combination thereof.

The dielectric film 30 may be located over the first electrode 10 along the inner wall of the interlayer insulating film 180 within the trench 181 and may be, for example, a continuous thin film formed with a substantially uniform thickness along the inner wall of the interlayer insulating film 180 within the trench 181. The thickness of the dielectric film 30 may be about 1 nm to 100 nm, and within this range, it may be about 2 nm to 80 nm, about 2 nm to 50 nm, or about 2 nm to 30 nm.

The second electrode 20 may fill the interior of the trench 181. However, it is not limited thereto and the second electrode 20 may fill a portion of the trench 181 and be filled with a filler material thereover. The second electrode 20 may include, for example, a metal, a metal nitride, a metal oxynitride, or a combination thereof, and may include, for example, Ti, TiN, TiON, TaN, MON, CON, TiAlN, TaAlN, W, Ru, Ir, IrO₂, Pt, or a combination thereof, but is not limited thereto.

A contact 150 may be located in the interlayer insulating film 180, and through the contact 150, the bit line 120 and an upper wiring layer may be electrically connected. A barrier layer 170 may be formed around the contact 150.

One or two or more interlayer insulating films 190 and 195 may be located over the capacitor 100, and the capacitor 100 may be electrically connected to a wiring (not shown) embedded in the interlayer insulating films 190 and 195.

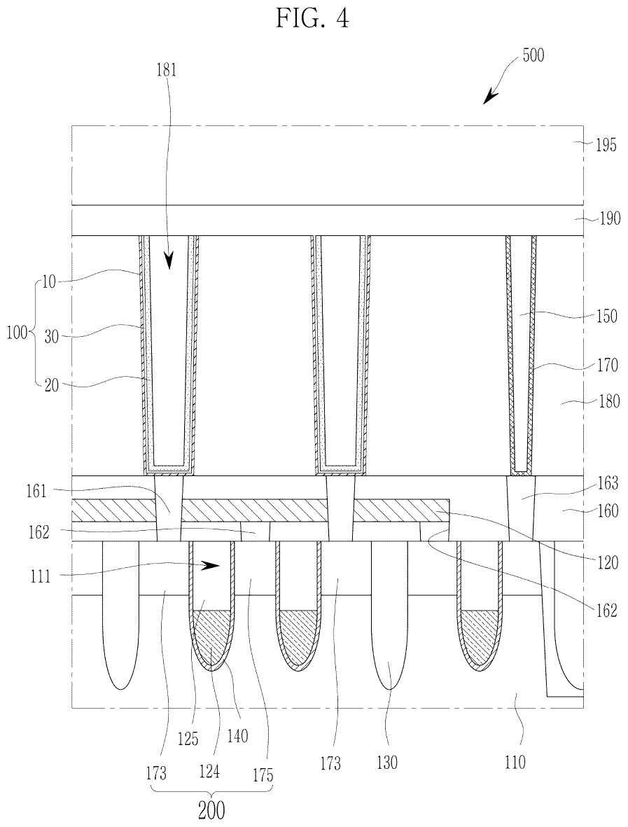

FIG. 4 is a cross-sectional view showing another example of a semiconductor device according to an embodiment.

Referring to FIG. 4, a semiconductor device 500 according to an embodiment includes, as in the above-described example, a semiconductor substrate 110, a transistor 200, and a capacitor 100. At least one of the transistor 200 and the capacitor 100 may include a thin film (for example, an oxide thin film or a strontium oxide thin film) formed by the thin film formation method described herein (for example, atomic layer deposition). The oxide thin film or the strontium oxide thin film may include strontium titanate (SrTiO₃), lanthanum strontium titanate, barium strontium titanate [BaₓSr₁₋ₓTiO₃ (where 0<x<1)], or a combination thereof.

In an embodiment, the semiconductor device 500 according to an embodiment may include a transistor 200 having a BCAT (buried cell array transistor) structure in which a gate electrode 124 and a gate insulating film 140 are embedded in the semiconductor substrate 110, but is not limited thereto.

The transistor 200 has a plurality of trenches 111. The trenches 111 are formed to a predetermined depth from the surface of the semiconductor substrate 110 and may expose an inner wall of the semiconductor substrate 110. The shape of the trenches 111 is not particularly limited and, for example, a connection portion between a bottom surface and a side surface of the trench 111 may have a rounded shape, or the side surface of the trench 111 may be inclined at a predetermined angle.

The gate insulating film 140 is located along the inner wall of the semiconductor substrate 110 within the trench 111. The gate insulating film 140 may include the above-described thin film and may be, for example, a strontium-containing oxide thin film as described herein. The oxide thin film or the strontium oxide thin film may include strontium titanate (SrTiO₃), lanthanum strontium titanate, barium strontium titanate [BaₓSr₁₋ₓTiO₃ (where 0<x<1)], or a combination thereof, as described herein. The gate insulating film 140 may be, for example, a continuous thin film formed with a substantially uniform thickness along the inner wall of the semiconductor substrate 110 within the trench 111 by the above-described atomic layer deposition method. The thickness of the gate insulating film 140 may be about 1 nm to 30 nm, and within this range, it may be about 3 nm to 20 nm or about 5 nm to 10 nm.

The gate electrode 124 may fill a portion of the trench 111. However, the gate electrode 124 is not limited thereto and may also be a continuous thin film located along the inner wall of the semiconductor substrate 110 within the trench 111 over the gate insulating film 140. The gate electrode 124 may include a low-resistance conductive material and may include, for example, Ti, TiN, TiON, or a combination thereof. The thickness of the gate electrode 124 may be about 1 nm to 30 nm, and within this range, it may be about 3 nm to 20 nm or about 5 nm to 10 nm.

A conductive filling layer 125 is formed over the gate electrode 124. The conductive filling layer 125 fills the trench 111 and may be electrically connected to a word line (not shown). The conductive filling layer 125 may include Ti, TiN, TiON, tungsten, or a combination thereof, but is not limited thereto.

Although the above description illustrates a DRAM device as one example of a semiconductor device, the embodiment is not limited thereto and may be applied to all semiconductor devices including an oxide film. For example, the semiconductor device may be used for arithmetic operations, program execution, and/or temporary data storage.

The semiconductor device of an embodiment may be included in various electronic devices. The electronic device may include, for example, a mobile device, a computer, a notebook, a tablet PC, a smart watch, a sensor, a digital camera, an electronic book, a network device, a vehicle navigation system, an Internet of Things (IoT) device, an Internet of Everything (IoE) device, a drone, a door lock, a safe, an automated teller machine (ATM), a security device, a medical device, or an automotive electronic component, but is not limited thereto. In an embodiment, the electronic device may include a memory unit, an arithmetic logic unit, and a control unit, which may be electrically connected to each other. For example, the memory unit, the arithmetic logic unit, and the control unit may be implemented as a single chip, and, for example, may be monolithically integrated on a single substrate to be implemented as one chip. The memory unit, the arithmetic logic unit, and the control unit may each independently include the aforementioned capacitor and/or semiconductor device. The electronic device may be connected to one or more input/output devices.

Specific examples are described below. However, the examples described below are only for specifically illustrating or explaining the disclosure, and the scope of the disclosure is not limited thereto.

### EXAMPLES

### [1] TGA Analysis

The TGA analysis was performed under a nitrogen gas atmosphere using an Auto-TGA Q500 system (TA Instruments) at a heating rate of 10 degrees Celsius per minute in a temperature range from 30 degrees Celsius to 410 degrees Celsius.

### [2] NMR Analysis

¹H NMR analysis was performed using an FT-NMR (AVANCE III HD 500 MHz) in a benzene-de solvent.

### Preparation Example 1

Ligand 1 and Compound 1 were synthesized according to the following reaction scheme:

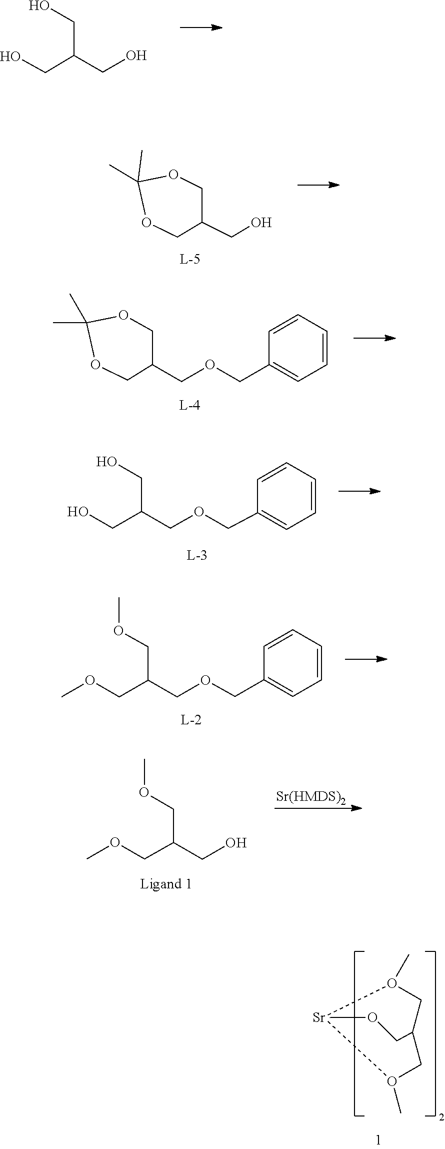

### Synthesis of Intermediate L-5

2-(Hydroxymethyl) propane-1,3-diol (18.0 g, 124.0 mmol) was dissolved in tetrahydrofuran (THF, 400 mL) in a reaction flask, and 4-toluenesulfonic acid monohydrate (1.0 g, 5.2 mmol) and 2,2-dimethoxypropane (23.5 mL, 190.4 mmol) were then added. The mixture was stirred at room temperature for about 6 hours. After completion of the reaction, the mixture was neutralized with triethylamine (10 mL), followed by removal of volatiles under reduced pressure. The residue was purified by liquid chromatography to obtain Intermediate L-5 (19.0 g, yield 78%).

LC-MS m/z=147 (M+H)⁺

### Synthesis of Intermediate L-4

NaH (60% in mineral oil, 4.5 g, 113.0 mmol) was added dropwise to THF (200 mL) in a reaction flask, and at 0° C., Intermediate L-5 (15.0 g, 102.6 mmol) dissolved in THF (50 mL) was slowly added. After stirring the reaction mixture at room temperature for about 2 hours, benzyl bromide (22.8 g, 133.4 mmol) was added, and the mixture was heated and stirred for 12 hours. After completion of the reaction, water and ethyl acetate were added, and the organic layer obtained from extraction was dried over magnesium sulfate, followed by removal of volatiles under reduced pressure. The residue was purified by liquid chromatography to obtain Intermediate L-4 (23.0 g, yield 96%).

LC-MS m/z=237 (M+H)⁺

### Synthesis of Intermediate L-3

Intermediate L-4 (20.0 g, 84.6 mmol) was dissolved in ethanol (100 mL), and 3 N HCl aqueous solution (50 mL) was slowly added dropwise, followed by stirring at room temperature for about 2 hours. After completion of the reaction, a product was obtained under reduced pressure, and the obtained residue was extracted with diethyl ether and purified by liquid chromatography to obtain Intermediate L-3 (16.5 g, yield 99%).

LC-MS m/z=197 (M+H)⁺

### Synthesis of Intermediate L-2

NaH (60% in mineral oil, 2.9 g, 73.5 mmol) was added dropwise to THF (100 mL) in a reaction flask, and at 0° C., Intermediate L-3 (6.0 g, 30.6 mmol) dissolved in THF (20 mL) was slowly added. The reaction mixture was stirred for about 2 hours, followed by the slow addition of methyl iodide (13.0 g, 91.8 mmol), and heated with stirring for 16 hours. After completion of the reaction, water and ethyl acetate were added, and the organic layer obtained from extraction was dried over magnesium sulfate. The resulting mixture was purified by liquid chromatography to obtain Intermediate L-2 (5.7 g, yield 83%).

LC-MS m/z=225 (M+H)⁺

### Synthesis of Ligand 1

The synthesized Intermediate L-2 (5.5 g, 24.5 mmol) was dissolved in ethanol (60 mL) in a reaction flask, and Pd/C (10 wt %, 0.6 g) was added. The reaction mixture was purged with H₂ gas and stirred at room temperature for one day. After completion of the reaction, the mixture was filtered through celite and purified by liquid chromatography to obtain Ligand 1 (3.1 g, yield 95%).

GC-MS m/z=135 (M+H)⁺

1H NMR (500 MHz, benzene-d6): δ 3.75-3.73 (m, 2H), 3.31 (d, 4H), 3.01 (s, 6H), 2.26 (br s, 1H), 2.05-2.03 (m, 1H).

### Synthesis of Compound 1

Strontium bis[bis(trimethylsilyl)amide] (Sr(HMDS)₂, purchased from Humist, Yuseong-gu, Daejeon, Republic of Korea) (2.0 g, 4.9 mmol) was dissolved in hexane (60 mL) in a reaction flask. A solution of Ligand 1 (1.3 g, 9.8 mmol) in hexane (20 mL) was slowly added dropwise, and the mixture was stirred at room temperature for 24 hours. After completion of the reaction, the mixture was filtered through Celite and subjected to fractional distillation under reduced pressure to obtain a strontium compound represented by the following formula (1.2 g, yield 73%). The obtained strontium compound was confirmed to be in a liquid state at room temperature (25 degrees Celsius).

1H NMR (500 MHz, benzene-d6): δ 4.23 (br s, 2H), 3.77 (br s, 2H), 3.66 (br s, 2H), 3.33 (s, 6H), 2.34 (br s, 1H).

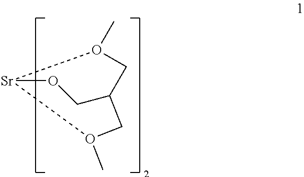

The molecular weight of the prepared strontium compound was calculated and summarized in Table 1.

### Preparation Example 2

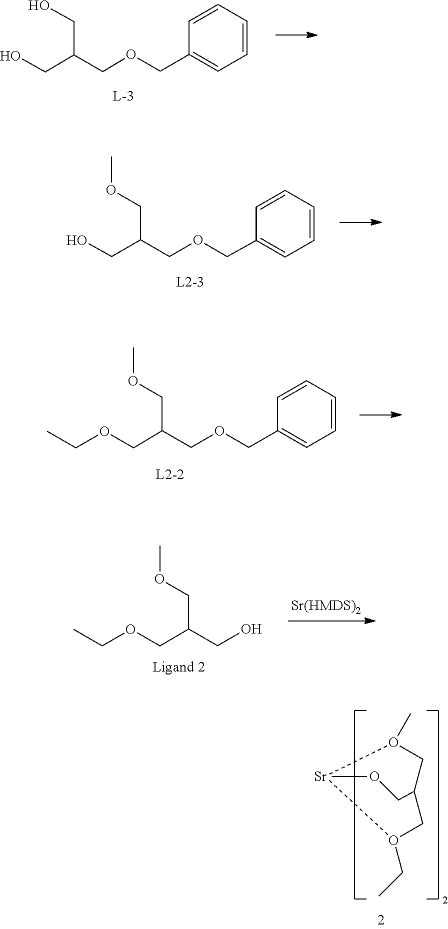

### Synthesis of Intermediate L2-3

Intermediate L2-3 (2.5 g, yield 70%) was obtained by the same method as the synthesis of Intermediate L-2 in Preparation Example 1, except that methyl iodide was used in a mole ratio of 1 equivalent.

LC-MS m/z=211 (M+H)⁺

### Synthesis of Intermediate L2-2

NaH (60% in mineral oil, 0.5 g, 12.6 mmol) was added dropwise to THF (60 mL) in a reaction flask, and at 0° C., Intermediate L2-3 (2.2 g, 10.5 mmol) dissolved in THF (10 mL) was slowly added. After stirring the reaction mixture for about 2 hours, ethyl iodide (2.5 g, 15.8 mmol) was slowly added, followed by heating and stirring for 12 hours. After completion of the reaction, water and ethyl acetate were added, and the organic layer obtained from extraction was dried over magnesium sulfate. The resulting mixture was purified by liquid chromatography to obtain Intermediate L2-2 (2.0 g, yield 80%).

LC-MS m/z=239 (M+H)⁺

### Synthesis of Ligand 2

Ligand-2 (1.2 g, yield 95%) was synthesized by the same method as the synthesis of Ligand-1 in Preparation Example 1, except that Intermediate L2-2 was used instead of Intermediate L-2.

GC-MS m/z=149 (M+H)⁺

1H NMR (500 MHz, benzene-d6): δ 3.76-3.74 (m, 2H), 3.37 (d, 2H), 3.19 (d, 2H), 3.18 (q, 2H), 3.01 (s, 3H), 2.23-2.22 (m, 1H), 2.07-2.05 (m, 1H), 1.00 (t, 3H).

### Synthesis of Compound 2

Compound 2 (0.9 g, yield 60%) was obtained by the same method as in Preparation Example 1, except that Ligand-2 was used instead of Ligand-1. The obtained strontium compound was confirmed to be in a liquid state at room temperature (25 degrees Celsius).

1H NMR (500 MHz, benzene-d6): δ 4.11 (br s, 1H), 4.07 (br s, 1H), 3.65 (br s, 3H), 3.57 (br s, 1H), 3.44-3.41 (br m, 2H), 3.27 (s, 3H), 2.27 (br s, 1H), 1.17-1.14 (m, 3H).

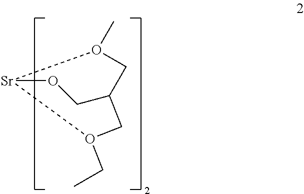

The molecular weight of the prepared strontium compound was calculated and summarized in Table 1.

### Preparation Example 3

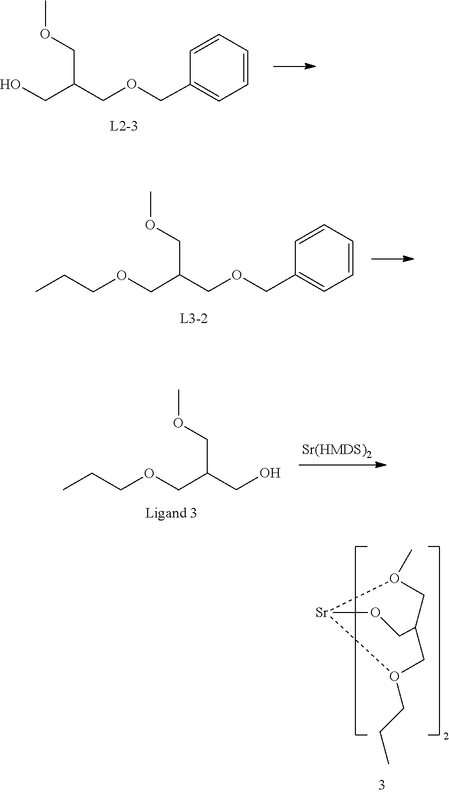

### Synthesis of Intermediate L3-2

Intermediate L3-2 (1.0 g, yield 78%) was synthesized by the same method as the synthesis of Intermediate L2-2 in Preparation Example 2, except that propyl iodide was used instead of ethyl iodide.

GC-MS m/z=253 (M+H)⁺

### Synthesis of Ligand 3

Ligand 3 (0.52 g, yield 80%) was synthesized by the same method as the synthesis of Ligand 1 in Preparation Example 1, except that Intermediate L3-2 was used instead of Intermediate L-2.

GC-MS m/z=163 (M+H)⁺

1H NMR (500 MHz, benzene-d6): δ 3.77-3.75 (m, 2H), 3.39 (d, 2H), 3.33 (d, 2H), 3.12 (t, 2H), 3.02 (s, 3H), 2.28-2.26 (m, 1H), 2.09-2.04 (m, 1H), 1.42 (q, 2H), 0.81 (t, 3H).

### Synthesis of Compound 3

Compound 3 (1.1 g, yield 85%) was obtained by the same method as in Preparation Example 1, except that Ligand-3 was used instead of Ligand-1. The obtained strontium compound was confirmed to be in a liquid state at room temperature (25° C.).

1H NMR (500 MHz, benzene-d6): δ 4.30 (br s, 1H), 4.18 (br s, 1H), 3.86 (br s, 2H), 3.79-3.58 (br m, 3H), 3.47 (br s, 4H), 2.37 (br s, 1H), 1.67-1.64 (br m, 2H), 0.96 (t, 3H).

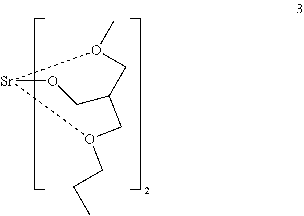

The molecular weight of the prepared strontium compound was calculated and summarized in Table 1.

### Preparation Example 4

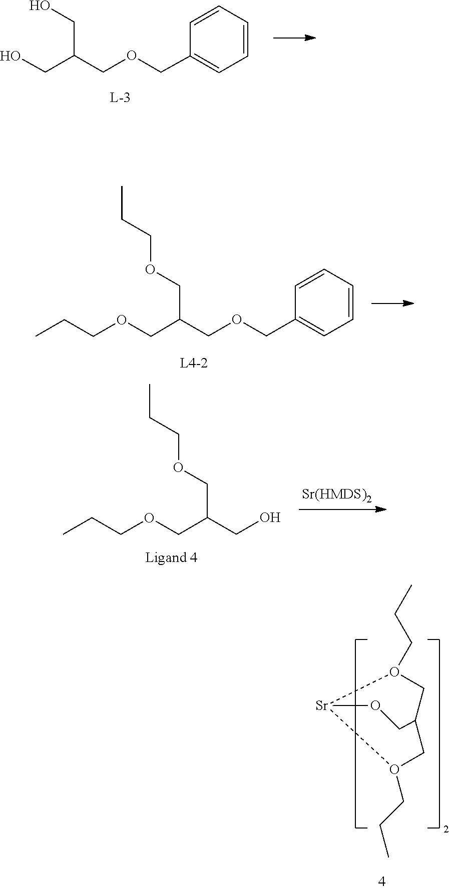

### Synthesis of Intermediate L4-2

Intermediate L4-2 (0.6 g, yield 60%) was synthesized by the same method as the synthesis of Intermediate L-2 in Preparation Example 1, except that propyl iodide was used instead of methyl iodide.

LC-MS m/z=281 (M+H)⁺

### Synthesis of Ligand 4

Ligand 4 (0.37 g, yield 90%) was synthesized by the same method as the synthesis of Ligand 1 in Preparation Example 1, except that Intermediate L4-2 was used instead of Intermediate L-2.

GC-MS m/z=192 (M+H)⁺

1H NMR (500 MHz, benzene-d6): δ 3.81-3.79 (m, 2H), 3.44-3.39 (m, 4H), 3.14 (t, 4H), 2.40-2.37 (m, 1H), 2.11-2.09 (m, 1H), 1.47-1.40 (m, 4H), 0.82 (t, 6H).

Synthesis of Compound 4 Compound 4 (0.4 g, yield 83%) was obtained by the same method as in Preparation Example 1, except that Ligand-4 was used instead of Ligand-1. The obtained strontium compound was confirmed to be in a liquid state at room temperature (25° C.).

1H NMR (500 MHz, benzene-d6): δ 4.27 (br s, 2H), 3.89-3.82 (br m, 4H), 3.57 (br s, 4H), 2.40 (br s, 1H), 1.84-1.74 (br m, 4H), 0.99 (br s, 6H).

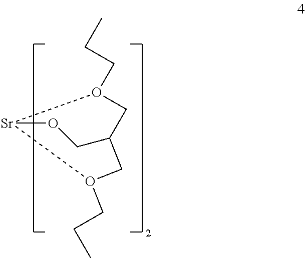

The molecular weight of the prepared strontium compound was calculated and summarized in Table 1.

### Preparation Example 5

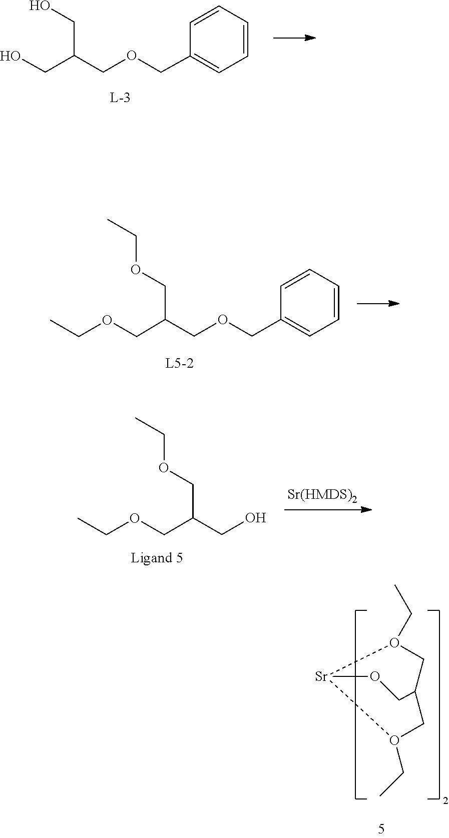

### Synthesis of Ligand 5

Ligand 5 (0.6 g, yield 50%) was synthesized by the same method as the synthesis of Intermediate L-2 and Ligand-1 in Preparation Example 1, except that ethyl iodide was used instead of methyl iodide.

1H NMR (500 MHz, benzene-d6): δ 3.76-3.75 (m, 2H), 3.37 (d, 2H), 3.32 (d, 2H), 3.17 (q, 2H), 3.01 (s, 3H), 2.23 (br s, 1H), 2.07-2.04 (m, 1H), 1.00 (t, 3H).

### Synthesis of Compound 5

Compound 5 (0.6 g, yield 75%) was obtained by the same method as in Preparation Example 1, except that Ligand-5 was used instead of Ligand-1. The obtained strontium compound was confirmed to be in a liquid state at room temperature (25° C.).

1H NMR (500 MHz, benzene-d6): δ 4.13 (br s, 2H), 3.78-3.75 (br m, 4H), 3.56 (br s, 4H), 2.37 (br s, 1H), 1.22 (br s, 6H).

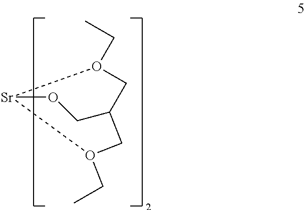

The molecular weight of the prepared strontium compound was calculated and summarized in Table 1.

### Preparation Example 6

Ligand 7 and Compound 7 were synthesized according to the following reaction scheme:

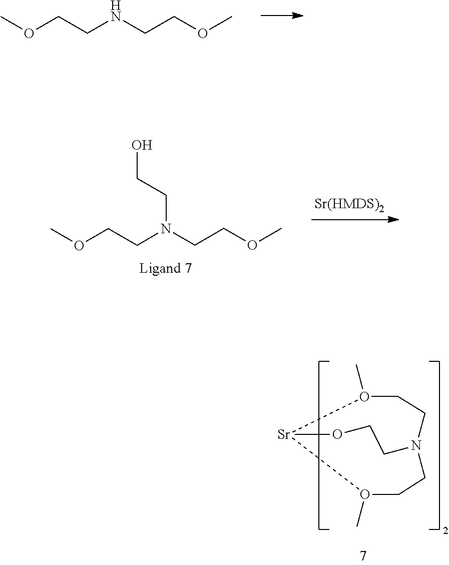

### Synthesis of Ligand 7

To a mixture of bis(2-methoxyethyl)amine (13.3 g, 99.8 mmol) and 2-chloroethanol (8.0 g, 99.8 mmol) in a reaction flask was added with KI (0.2 g, 1 mmol) and K₂CO₃ (41.3 g, 300.0 mmol), followed by heating and stirring at 80° C. for 18 hours. After completion of the reaction, the reaction mixture was purified by liquid chromatography using a mixed solvent of ethyl acetate and ethanol (9:1) to obtain Ligand 7 (5.3 g, yield 30%).

1H NMR (500 MHz, benzene-d6): δ 3.66 (t, 2H), 3.39 (t, 4H), 3.10 (s, 6H), 2.77-2.75 (m, 6H).

### Synthesis of Compound 7

Compound 7 (0.8 g, yield 56%) was obtained by the same method as in Preparation Example 1, except that Ligand-7 was used instead of Ligand-1. The obtained strontium compound was confirmed to be in a liquid state at room temperature (25° C.).

1H NMR (500 MHz, benzene-d6): δ 4.46-4.26 (br m, 2H), 3.56 (br s, 4H), 3.30 (br s, 6H), 3.17-3.06 (m, 4H), 2.94 (br s, 2H).

### Reference Example 1

A compound having the following structure was obtained from STREM Chemicals:

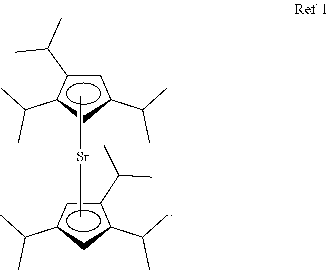

### Reference Example 2

A compound having the following structure was synthesized according to the following reaction scheme:

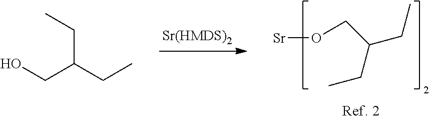

### Synthesis of Ref 2

Ref 2 was synthesized by the same method as in Preparation Example 1, except that 2-ethylbutyl alcohol (purchased from TCI) was used instead of Ligand-1. The obtained strontium compound was confirmed to be in a solid state at room temperature (25° C.). 1H NMR (500 MHz, benzene-d6): δ 3.79 (br s, 2H), 1.63 (br s, 2H), 1.47 (br s, 3H), 1.07 (br s, 6H).

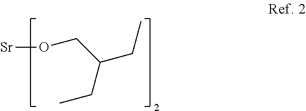

### Reference Example 3

A compound having the following structure, Ref 3, was synthesized according to the following reaction scheme:

### Synthesis of Ref 3

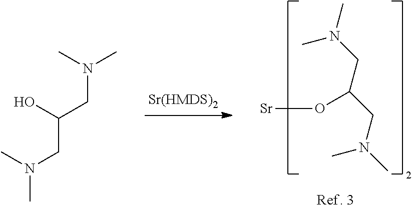

Ref 3 was synthesized by the same method as in Preparation Example 1, except that 1,3-bis(dimethylamino)-2-propanol (purchased from Combi-blocks) was used instead of Ligand-1. The obtained strontium compound was confirmed to be in a solid (polymeric) state at room temperature (25° C.).

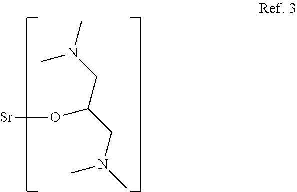

### Experimental Example 1

Thermogravimetric analysis (TGA) was performed on the strontium compounds synthesized in Preparation Examples 1 to 6 (Examples 1 to 6), as well as the compounds of Reference Example 1 (Comparative Example 1) and Reference Example 2 (Comparative Example 2).

The thermogravimetric analysis can indicate the volatility of each compound. The temperature at 10% weight loss (T₉₀%) and the temperature at 50% weight loss (T₅₀%) were each measured, and the results were summarized in Table 1.

TABLE 1

| | | | | | state of the |
|---|---|---|---|---|---|
| | precursor | M.W | T_{90%} | T_{50%} | strontium |
| | (#) | (g/mol) | (° C.) | (° C.) | compound |
| Example 1 | 1 | 353.9 | 149 | 192 | liquid |
| Example 2 | 2 | 382.0 | 129 | 198 | liquid |
| Example 3 | 3 | 410.1 | 155 | 212 | liquid |
| Example 4 | 4 | 466.2 | 157 | 204 | liquid |
| Example 5 | 5 | 410.1 | 135 | 180 | liquid |
| Example 6 | 7 | 440.1 | 144 | 197 | liquid |
| Comp. | Ref. 1 | 470.3 | 206 | 264 | solid |
| Example 1 | | | | | |
| Comp. | Ref. 2 | 289.95 | 159 | 408 | solid |
| Example 2 | | | | | |
| Comp. | Ref. 3 | 378.07 | 215 | 360 | solid |
| Example 3 | | | | | |

The cyclopentadiene-type compound (Ref. 1, Comparative Example 1), which is conventionally used as a strontium precursor, exhibited T₉₀% and T₅₀% values exceeding 200° C., and it was confirmed that the compound was in a solid state. The strontium compound having a ligand structure that does not satisfy Chemical Formula 1 (Ref. 2, Comparative Example 2) showed a relatively low T₉₀% value; however, its T₅₀% exceeded 400° C., indicating very low volatility. Similarly, the strontium compound having a ligand structure that does not satisfy Chemical Formula 1 (Ref. 3, Comparative Example 3) exhibited a relatively low T₉₀% value, but its T₅₀% was around 360° C., also indicating very low volatility.

All of the strontium compounds of Comparative Examples 1 to 3 were confirmed to be in a solid state at room temperature.

In contrast, the strontium compounds synthesized in Preparation Examples 1 to 6 exhibited relatively low T₉₀% and T₅₀% values, suggesting that these compounds have improved volatility compared to those of the comparative examples.

Furthermore, these results indicate that the strontium compounds synthesized in Preparation Examples 1 to 6 may exhibit high vapor pressure and volatility when applied, for example, to thin-film formation processes through vapor deposition.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTiON OF SYMBOLS

10: first electrode
20: second electrode
30: dielectric film
100: capacitor
110: semiconductor substrate
120: bit line
124: gate electrode
125: conductive filling layer
130: shallow trench isolation (STI)
140: gate insulating film
150: contact
160, 180: interlayer insulating film
161, 162: contact
170: barrier layer
173: source region
175: drain region
181, 111: trench
190, 195: interlayer insulating film
200: transistor
500: semiconductor device

What is claimed is:

1. A strontium compound represented by Chemical Formula 1: 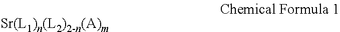
In Chemical Formula 1,
L1 is a first ligand represented by Chemical Formula 2,
L₂ is a second ligand different from the first ligand,
A is an third ligand including oxygen or nitrogen,
n is 1 or 2, and
m is 0, 1, 2, 3, or 4, 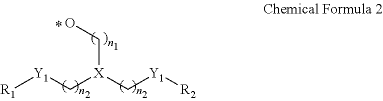
In Chemical Formula 2, X is nitrogen or CR, where R of CR is hydrogen or a substituted or unsubstituted C1 to C10 alkyl group,
* denotes hydrogen or a binding site to strontium,
₁ is 1 or 2,
each n₂ is independently 1, 2, or 3,
each Y₁ is independently O or NR, where R of NR is hydrogen or a substituted or unsubstituted C1 to C10 alkyl group, and
₁ and R₂ are each independently a substituted or unsubstituted C1 to C5 alkyl group or a Si-containing organic group.

2. The strontium compound of claim 1, wherein n in Chemical Formula 1 is 2.

3. The strontium compound of claim 1, wherein the second ligand comprises a substituted or unsubstituted alkyl group, a substituted or unsubstituted alkoxy group, a substituted or unsubstituted acetylacetonate group, a substituted or unsubstituted diketone moiety, a substituted or unsubstituted ketoiminate moiety, a substituted or unsubstituted β-ketostearate moiety, a substituted or unsubstituted diiminate moiety, a carbonyl group, a substituted or unsubstituted alkylcarbonyl group, a substituted or unsubstituted acetoxy group, a substituted or unsubstituted dialkylamido group, a substituted or unsubstituted acetamidinate group, a substituted or unsubstituted phenanthroline group, a substituted or unsubstituted glyoximate group, a substituted or unsubstituted carbamate group, a substituted or unsubstituted cyclopentadienyl group, a substituted or unsubstituted pyrrolyl group, a substituted or unsubstituted alkoxide group, a substituted or unsubstituted amidinate group, a substituted or unsubstituted imidazolyl moiety, or a trispyrazolyl borate moiety, or a combination thereof.

4. The strontium compound of claim 1, wherein the first ligand is represented by Chemical Formula 2-1 or Chemical Formula 2-2: 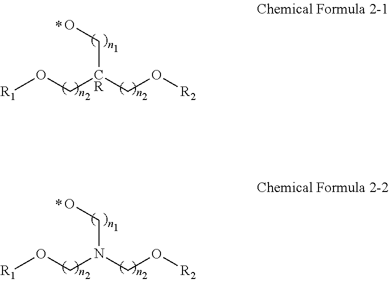
In Chemical Formula 2-1 or Chemical Formula 2-2,
* denotes hydrogen or a binding site to strontium,
n₁ is 1 or 2,
n₂ is independently 1 to 3,
R is hydrogen or a substituted or unsubstituted C1 to C10 alkyl group, and
R₁ is a substituted or unsubstituted C1 to C5 alkyl group or a Si-containing organic group, and
R₂ is a substituted or unsubstituted C1 to C5 alkyl group or a Si-containing organic group.

5. The strontium compound of claim 1, wherein the first ligand is a compound represented by Chemical Formula 2-3 or Chemical Formula 2-4: 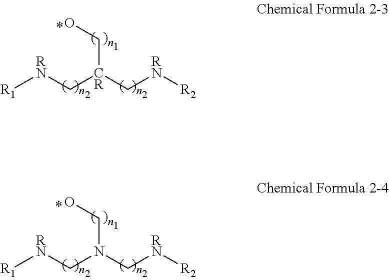
In Chemical Formula 2-3 or Chemical Formula 2-4,
* denotes hydrogen or a binding site to strontium,
n₁ is 1 or 2,
n₂ is independently 1 to 3,
R of CR and NR are the same or different and each R is independently hydrogen or a substituted or unsubstituted C1 to C10 alkyl group,
R₁ is a substituted or unsubstituted C1 to C5 alkyl group or a Si-containing organic group, and
R₂ is a substituted or unsubstituted C1 to C5 alkyl group or a Si-containing organic group.

6. The strontium compound of claim 1, wherein the third ligand comprises a dialkoxyalkane, tetrahydrofuran, pyridine, a dialkyl ether, or a combination thereof.

7. The strontium compound of claim 1, wherein m is 0.

8. The strontium compound of claim 1, wherein the strontium compound is represented by any of the following formulae:

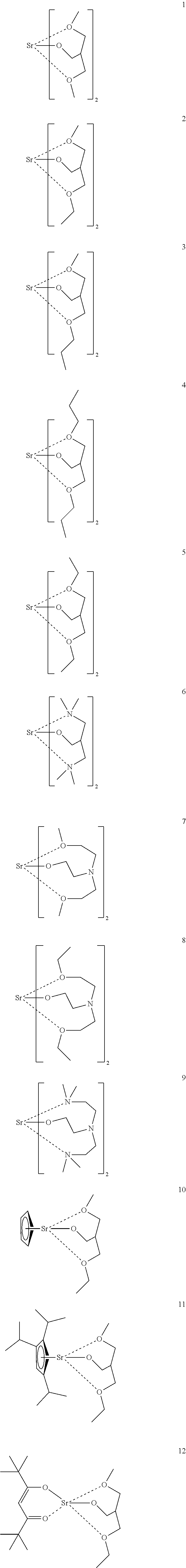

9. The strontium compound of claim 1, wherein the strontium compound is in a liquid state at a temperature of greater than or equal to about 20° C. and less than or equal to about 50° C.

10. A method of forming an oxide thin film comprising performing a strontium cycle to obtain a thin film including a strontium-containing oxide,
wherein the strontium cycle comprises:
supplying a gas including a strontium precursor into a process chamber including a substrate;
supplying an inert gas into the process chamber to purge excess of the strontium precursor from the process chamber; and
supplying a co-reactant, optionally with an oxidizing agent, into the process chamber;
optionally supplying an inert gas into the process chamber to purge excess of the co-reactant, and optionally, the oxidizing agent,
wherein the strontium precursor includes the strontium compound of claim 1.

11. The method of claim 10, wherein the strontium compound is represented by Chemical Formula 2-1 or Chemical Formula 2-2: 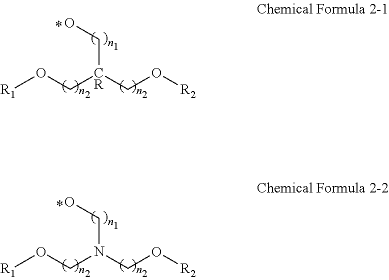
In Chemical Formula 2-1 or Chemical Formula 2-2,
* denotes hydrogen or a binding site to strontium,
n₁ is 1 or 2,
n₂ is independently 1 to 3,
R is hydrogen or a substituted or unsubstituted C1 to C10 alkyl group, and
R₁ is a substituted or unsubstituted C1 to C5 alkyl group or a Si-containing organic group, and
R₂ is a substituted or unsubstituted C1 to C5 alkyl group or a Si-containing organic group.

12. The method of claim 10, wherein the first ligand is represented by Chemical Formula 2-3 or Chemical Formula 2-4: 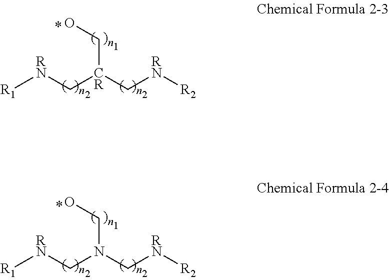
In Chemical Formula 2-3 or Chemical Formula 2-4,
* denotes hydrogen or a binding site to strontium,
n₁ is 1 or 2,
n₂ is independently 1 to 3,
R of CR and NR are the same or different and each R is independently hydrogen or a substituted or unsubstituted C1 to C10 alkyl group,
R₁ is a substituted or unsubstituted C1 to C5 alkyl group or a Si-containing organic group, and
R₂ is a substituted or unsubstituted C1 to C5 alkyl group or a Si-containing organic group.

13. The method of claim 10, wherein the strontium compound is represented by any of the following formulae:

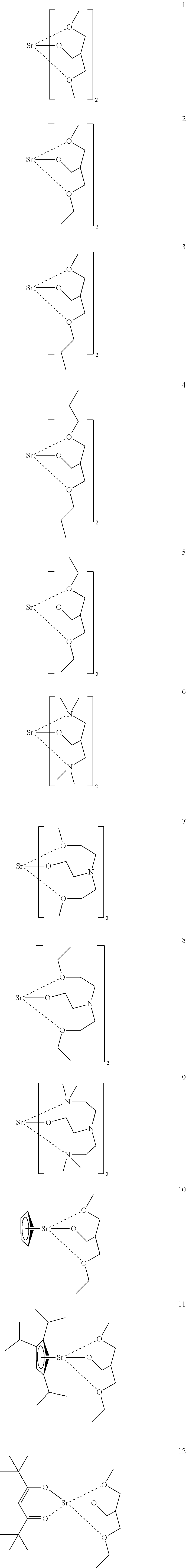

14. The method of claim 10, further comprising a first metal cycle,
wherein the first metal cycle comprises:
supplying a gas including a first metal precursor into the process chamber;
supplying an inert gas into the process chamber to purge excess of the first metal precursor; and
supplying a reactant for reaction with the first metal precursor into the process chamber,
wherein the first metal precursor comprises titanium, barium, ruthenium, or a combination thereof.

15. The method of claim 14, wherein the method comprises a plurality of the strontium cycles and a plurality of the first metal cycles.

16. The method of claim 10, wherein the co-reactant comprises water vapor, oxygen, hydrogen, ozone, hydrogen peroxide, or a combination thereof.

17. A method of manufacturing a semiconductor device comprising:
providing a transistor integrated into or disposed on a semiconductor substrate; and
providing a capacitor electrically connected to the transistor,
wherein at least one of the providing the transistor or the capacitor includes forming an oxide thin film by the method according to claim 12.

18. The method of claim 17, wherein the providing of the capacitor comprises:
providing a first electrode,
forming the oxide thin film, and
providing a second electrode.

19. The method of claim 17, wherein the providing of the transistor comprises:
providing a trench in the semiconductor substrate,
forming the oxide thin film in the trench, and
providing a gate conductor on the oxide thin film.

20. The method of claim 17, wherein the oxide thin film includes a strontium titanate (SrTiO₃), a lanthanum strontium titanate, a barium strontium titanate [BaₓSr₁₋ₓTiO₃ (wherein 0<x<1)], or a combination thereof.
